(19) United States
(12) Patent Application Publication
(10) Pub. No.: US 2025/0024714 A1
(43) Pub. Date: Jan. 16, 2025

(54) LIGHT EMITTING DISPLAY DEVICE

(71) Applicant: Samsung Display Co., Ltd., Yongin-Si (KR)

(72) Inventors: NUREE UM, Yongin-si (KR); Tae Hoon KWON, Yongin-si (KR); CHOONGHEE OH, Yongin-si (KR); Yu-Jin JEON, Yongin-si (KR); JAEWON CHO, Yongin-si (KR)

(21) Appl. No.: 18/648,782

(22) Filed: Apr. 29, 2024

(30) Foreign Application Priority Data
Jul. 10, 2023 (KR) 10-2023-0089091

(51) Int. Cl. H10K 59/126; H10K 59/121; H10K 59/131; H10K 77/10; H10K 102/00

(52) U.S. Cl. CPC H10K 59/126; H10K 59/1213; H10K 59/131; H10K 77/111; H10K 2102/311

(57) ABSTRACT

According to example embodiments, a light emitting display device includes a transistor, a driving voltage line, a driving voltage connecting electrode, an initialization control line, an output current passing region, and a shielding layer, wherein the initialization control line is disposed on one side of a channel of the transistor in a plan view of the output current passing region and overlaps the shielding layer, and the shielding layer is connected to the driving voltage line through the driving voltage connecting electrode.

### CROSS-REFERENCE TO RELATED APPLICATION

This application claims priority to and the benefit of Korean Patent Application No. 10-2023-0089091 filed at the Korean Intellectual Property Office on Jul. 10, 2023, the entire contents of which are incorporated herein by reference.

### BACKGROUND

### 1. Field

The present disclosure relates to a light emitting display device.

### 2. Description of the Related Art

The display device is a device that displays images, and includes a liquid crystal display (LCD), an organic light emitting diode (OLED), or the like.

Such display devices are used in various electronic devices such as mobile phones, navigation devices, digital cameras, electronic books, portable game consoles, and various terminals.

A display device such as an organic light emitting display device may have a bendable or foldable structure by using a flexible substrate.

In addition, in small electronic devices such as mobile phones, optical elements such as cameras and optical sensors are formed in the bezel area around the display area, but as the size of the display screen is increased, the size of the area around the display area gradually decreases. A technology that can dispose an optical sensor on the back of the display area is being developed.

### SUMMARY

Embodiments are intended to provide a light emitting display device in which display quality is not deteriorated due to signal interference.

A light emitting display device according to an embodiment includes a first semiconductor layer disposed on a substrate and including a channel of a driving transistor, a channel of a sixth transistor, and an output current passing region disposed on one side of the channel of the sixth transistor; a first gate conductive layer disposed on the first semiconductor layer and including a gate electrode of the driving transistor overlapping the channel of the driving transistor and an emission control line overlapping the channel of the sixth transistor, a second gate conductive layer disposed on the first gate conductive layer and including a first storage electrode overlapping the gate electrode of the driving transistor and a shielding layer overlapping the output current passing region in a plan view, a second semiconductor layer disposed on the second gate conductive layer and including a channel of a fourth transistor, a third gate conductive layer disposed on the second semiconductor layer and including an initialization control line overlapping the channel of the fourth transistor, a first data conductive layer disposed on the third gate conductive layer and including a driving voltage connecting electrode and a first anode connecting electrode electrically connected to the output current passing region disposed on one side of the channel of the sixth transistor, a first organic layer covering the first data conductive layer, a second data conductive layer disposed on the first organic layer and including a second anode connecting electrode electrically connected to the first anode connecting electrode and a driving voltage line, second organic layers disposed on the second data conductive layer; and an anode disposed on the second organic layer and electrically connected to the second anode connecting electrode, wherein the initialization control line overlaps the output current passing region and the shielding layer disposed on one side of the channel of the sixth transistor in a plan view, and the shielding layer is connected to the driving voltage line through the driving voltage connecting electrode.

The aforementioned second gate conductive layer further includes a lower shielding layer of the aforementioned fourth transistor, and the lower shielding layer of the aforementioned fourth transistor is electrically connected to the aforementioned initialization control line, and can overlap the aforementioned channel of the fourth transistor in a plan view.

The second gate conductive layer further includes a lower second scan line, the second semiconductor layer further includes a channel of a third transistor, and the third gate conductive layer further includes an upper second scan line, the channel of the third transistor may overlap the lower second scan line and the upper second scan line in a plan view, and the same signal may be applied to the lower second scan line and the upper second scan line.

The first semiconductor layer further includes the channel of the seventh transistor, one end of the seventh transistor is connected to the second initialization voltage line, and the output current transfer area can be located between the channel of the seventh transistor and the channel of the sixth transistor.

The first semiconductor layer further includes a channel of the fifth transistor, one end of the fifth transistor is connected to the driving voltage line, and the channel of the sixth transistor and the channel of the fifth transistor can overlap the light emitting control line in a plan view.

The first semiconductor layer may further include a channel of a second transistor, and one end of the second transistor may be connected to a data line.

A third data conductive layer is located between the second organic layer and the anode, and disposed above the second organic layer; and it may further include a third organic layer covering the third data conductive layer, and the anode can be located directly above the third organic layer.

The data line may be located in the third data conductive layer.

The third data conductive layer may further include a third anode connecting electrode, and the third anode connecting electrode may connect the second anode connecting electrode to the anode.

A metal layer is disposed between the substrate and the first semiconductor layer and includes an extension; and a buffer layer is disposed between the metal layer and the first semiconductor layer, wherein the extension portion of the metal layer may overlap the channel of the driving transistor in a plan view.

The light emitting display device according to the embodiment is located on a substrate, and includes a first semiconductor layer containing a channel of the driving transistor, a first gate conductive layer located above the first semiconductor layer and including a gate electrode of the driving transistor overlapping the channel of the driving transistor, a second gate conductive layer disposed on the first gate conductive layer and including a first storage electrode overlapping the gate electrode in a plan view and a lower shielding layer, a second semiconductor layer located above the second gate conductive layer and including a channel of the fourth transistor overlapping in plane with the lower shielding layer, a third gate conductive layer located above the second semiconductor layer and including an initialization control line overlapping the channel of the fourth transistor, a first data conductive layer located above the third gate conductive layer and including a first connection electrode connecting one side of the gate electrode of the driving transistor and the channel of the fourth transistor, and a first anode connecting electrode, a first organic film covering the first data conductive layer, a second data conductive layer located above the first organic film and including a second anode connecting electrode electrically connected to the first anode connecting electrode, and a driving voltage line, a second organic film located above the second data conductive layer, and an anode located above the second organic film and electrically connected to the second anode connecting electrode, where the lower shielding layer has an island structure, and the initialization control line is electrically connected to the lower shielding layer through an opening.

The second gate conductive layer further includes a lower second scan line, the second semiconductor layer further includes a channel of a third transistor, and the third gate conductive layer further includes an upper second scan line, the channel of the third transistor may overlap the lower second scan line and the upper second scan line in a plan view, and the same signal may be applied to the lower second scan line and the upper second scan line.

The first semiconductor layer further includes a channel of a sixth transistor and an output current-carrying region disposed on one side of the channel of the sixth transistor, and the second gate conductive layer further includes a shielding layer overlapping the output current-carrying region in a plan view, the initialization control line overlaps the output current-passing region disposed on one side of the channel of the sixth transistor and the shielding layer in a plan view, and the shielding layer may be connected to the driving voltage line.

The first semiconductor layer further includes a channel of a seventh transistor and one end of the seventh transistor is connected to a second initialization voltage line, and the output current-passing region comprises the channel of the seventh transistor and the sixth transistor.

The first semiconductor layer further includes a channel of a fifth transistor, one end of the fifth transistor is connected to the driving voltage line, and the channel of the sixth transistor and the channel of the fifth transistor overlapping the light emitting control line in a plan view.

The first semiconductor layer may further include a channel of a second transistor, and one end of the second transistor may be connected to a data line.

A third data conductive layer is disposed between the second organic layer and the anode and disposed on the second organic layer; a third organic layer covers the third data conductive layer, and the anode may be disposed directly on the third organic layer.

The data line may be located in the third data conductive layer.

The third data conductive layer may further include a third anode connecting electrode, and the third anode connecting electrode may connect the second anode connecting electrode to the anode.

A metal layer is disposed between the substrate and the first semiconductor layer and includes an extension; and a buffer layer is disposed between the metal layer and the first semiconductor layer, wherein the extension portion of the metal layer may overlap the channel of the driving transistor in a plan view.

According to the embodiments, when the voltage level of the initialization control signal (GI) applied to the fourth transistor changes, the amount of the light emitting current delivered to the light emitting diode is kept constant by the shielding layer to prevent deterioration of display quality.

According to embodiments, an initialization control line for transmitting the initialization control signal GI to the fourth transistor is formed as a single layer, an island-shaped lower shielding layer is formed under the semiconductor layer included in the fourth transistor, and the initialization control signal (GI) is transmitted so that the fourth transistor is properly controlled, and leakage current is not generated in the fourth transistor so that display quality is not deteriorated.

### BRIEF DESCRIPTION OF THE DRAWINGS

FIG. 1 is a schematic perspective view illustrating a use state of a display device according to an embodiment.

FIG. 2 is an exploded perspective view of a display device according to an embodiment.

FIG. 3 is a block diagram of a display device according to an embodiment.

FIG. 4 is a perspective view schematically illustrating a light emitting display device according to another embodiment.

FIG. 5 is a plan view illustrating an enlarged portion of a light emitting display device according to an embodiment.

FIG. 6 is a circuit diagram of one pixel included in a light emitting display device according to an embodiment.

FIG. 7, 8, 9, 10, 11, 12, 13, 14, 15, 16, 17, 18, 19, 20 and FIG. 21 are diagrams specifically illustrating the structure of each layer according to the manufacturing order of the lower panel layer in the light emitting display device according to an embodiment.

FIG. 22 is a cross-sectional view of a light emitting display device according to an embodiment.

FIG. 23 is a top plan view illustrating the vicinity of an initialization control line in a light emitting display device according to an embodiment.

FIG. 24 is a cross-sectional view along the XXIV-XXIV section line in FIG. 23;

FIG. 25 is a top plan view illustrating the vicinity of an initialization control line in a light emitting display device according to a comparative example.

FIG. 26 is a cross-sectional view along the XXVI-XXVI section line of FIG. 25;

FIG. 27 and FIG. 28 are views comparing and explaining differences in characteristics based on comparative examples and embodiments.

FIG. 29 is a cross-sectional view of a light emitting display device according to another embodiment.

### DETAILED DESCRIPTION

Hereinafter, with reference to the accompanying drawings, various embodiments will be described in detail so that those skilled in the art can easily carry out the present inventive concept.

This inventive concept may be embodied in many different forms, and is not limited to the embodiments set forth herein.

In order to clearly describe the present inventive concept, parts irrelevant to the description are omitted, and the same reference numerals are assigned to the same or similar components throughout the specification.

In addition, since the size and thickness of each component shown in the drawings are arbitrarily shown for convenience of explanation, the present inventive concept is not necessarily limited to that which is shown.

In the drawings, the thickness is shown enlarged to clearly express the various layers and regions.

And in the drawings, for convenience of explanation, the thicknesses of some layers and regions are exaggerated.

Also, when a part such as a layer, film, region, plate, or component is said to be “above” or “on” another part, this is not only when it is “directly on” the other part, but also when there is another part in between.

Conversely, when a part is said to be “directly on” another part, it means that there is no other part in between.

In addition, being “above” or “on” a reference part means being located above or below the reference part, and does not necessarily mean being located “above” or “on” it in the opposite direction of gravity.

In addition, throughout the specification, when a certain component is said to “include,” it means that it may further include other components without excluding other components unless otherwise stated.

In addition, throughout the specification, when reference is made to a “planar image,” it means when the target part is viewed from above, and when reference is made to a “cross-sectional image,” it means when a cross-section of the target part cut vertically is viewed from the side.

In addition, throughout the specification, when “connected” is used, this does not only mean that two or more components are directly connected, but when two or more components are indirectly connected through other components, they are physically connected. In addition to being connected or electrically connected, parts that are referred to by different names depending on their location or function but are substantially integral may be connected to each other.

In addition, throughout the specification, when a portion such as a wiring, layer, film, region, plate, component, etc. “extends in a first direction or a second direction,” it means only a straight line extending in the corresponding direction. Instead, it is a structure that generally extends along the first direction or the second direction, and includes a structure that is bent at one part, has a zigzag structure, or extends while including a curved structure.

In addition, electronic devices (e.g., mobile phones, TVs, monitors, and notebook computers) including display devices and display panels described in the specification or display devices and display panels manufactured by the manufacturing method described in the specification, are not excluded from the scope of the present specification.

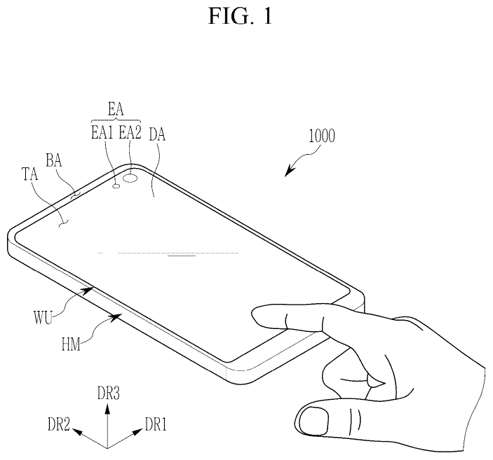

Hereinafter, a schematic structure of the display device will be described through FIG. 1 to FIG. 3.

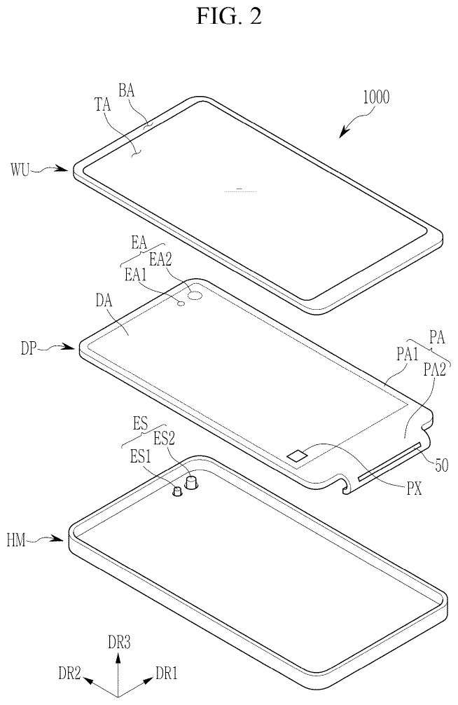

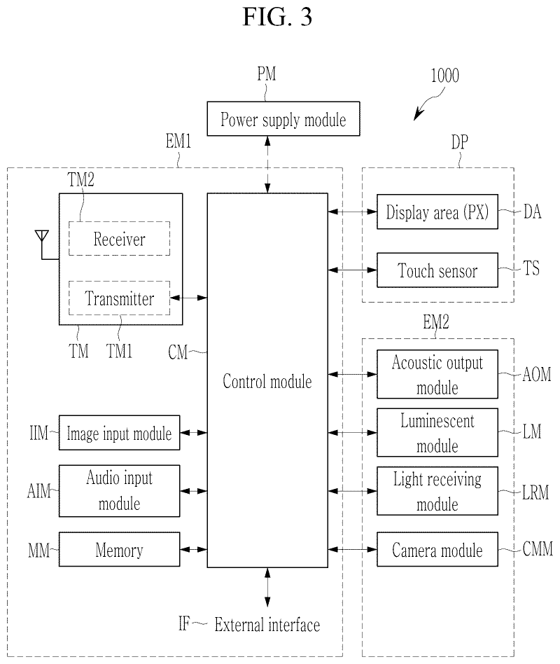

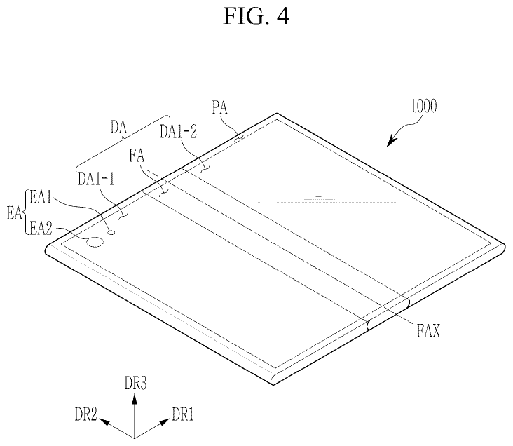

FIG. 1 is a schematic perspective view illustrating a display device according to an embodiment when a user is operating the display device, FIG. 2 is an exploded perspective view of the display device according to an embodiment, and FIG. 3 is a block diagram of the display device according to an embodiment.

Referring to FIG. 1, a display device 1000 according to an embodiment is a device for displaying a moving image or a still image, and may be a mobile phone, a smart phone, a tablet personal computer (PC), or a mobile phone. Not only portable electronic devices such as communication terminals, electronic notebooks, e-books, portable multimedia player (PMP), navigation, and ultra mobile PC (UMPC), but also televisions, laptops, monitors, billboards, Internet of things (IOT), etc., can be used as display screens for various products.

Also, the display device 1000 according to an embodiment can be used in wearable devices such as a smart watch, watch phone, glasses-type display, and head-mounted display (HMD).

In addition, the display device 1000 according to an embodiment includes a center information display (CID) disposed on an instrument panel of a vehicle, a center fascia or a dashboard of the vehicle, or a room mirror display instead of a side mirror of the vehicle (room mirror display), entertainment for the back seat of the vehicle, and can be used as a display placed on the back of the front seat of the vehicle.

FIG. 1 shows that the display device 1000 is used as a smart phone, for convenience of explanation.

The display device 1000 may display an image in a third direction DR3 on a display surface parallel to each of the first and second directions DR1 and DR2.

The display surface on which the image is displayed may correspond to the front surface of the display device 1000, and may correspond to the front surface of the cover window WU.

The image may include a still image as well as a dynamic image.

In this embodiment, the front (or upper) surface and rear (or lower) surface of each member are defined based on the direction in which the image is displayed.

The front surface and the rear surface oppose each other in the third direction DR3, and a normal direction of each of the front surface and the rear surface may be parallel to the third direction DR3.

The separation distance between the front and rear surfaces in the third direction DR3 may correspond to the thickness of the display panel in the third direction DR3.

The display device 1000 according to an embodiment may detect a user's input (refer to a hand in FIG. 1) applied from the outside.

The user's input may include various types of external inputs, such as a part of the user's body, light, heat, or pressure.

In one embodiment, the user's input is shown as the user's hand being applied in the foreground.

However, the present inventive concept is not limited thereto.

The user's input may be provided in various forms, and the display device 1000 may detect the user's input applied to the side or rear surface of the display device 1000 according to the structure of the display device 1000.

Referring to FIG. 1 and FIG. 2, the display device 1000 may include a cover window WU, a housing HM, a display panel DP, and an optical element ES.

In one embodiment, the cover window WU and the housing HM may be combined to form the exterior of the display device 1000.

The cover window WU may include an insulating panel.

For example, the cover window WU may be made of glass, plastic, or a combination thereof.

The front surface of the cover window WU may define the front surface of the display device 1000.

The transmission area TA may be an optically transparent area.

For example, the transmission area TA may have a visible light transmittance of about 90% or more.

The blocking area BA may define the shape of the transmission area TA.

The blocking area BA may be disposed adjacent to the transmission area TA, and may surround the transmission area TA.

The blocking area BA may have relatively low light transmittance compared to the transmission area TA.

The blocking area BA may include an opaque material that blocks light.

The blocking area BA may have a predetermined color.

The blocking area BA may be defined by a bezel layer provided separately from the transparent substrate defining the transmission area TA, or may be defined by an ink layer inserted into or colored in the transparent substrate.

The display panel DP may include display pixels PX displaying an image and the driving unit 50, and the display pixels PX are located in the display area DA.

The display panel DP may include a front surface including the display area DA and a non-display area PA.

The display area DA may be an area including display pixels in which the pixels operate according to electrical signals to emit light.

In an embodiment, the display area DA may be an area including pixels and displaying an image, and may also be an area where a touch sensor is positioned above the pixel in the third direction DR3 to detect an external input.

The transmission area TA of the cover window WU may at least partially overlap the display area DA of the display panel DP.

For example, the transmission area TA may overlap the entire surface of the display area DA or may overlap at least a portion of the display area DA.

Accordingly, the user may view the image through the transmission area TA or provide an external input based on the image.

However, the present inventive concept is not limited thereto.

For example, within the display area DA, an area where an image is displayed and an area where an external input is sensed may be separated from each other.

The non-display area PA of the display panel DP may at least partially overlap the blocking area BA of the cover window WU.

The non-display area PA may be an area covered by the blocking area BA.

The non-display area PA is disposed adjacent to the display area DA and may surround the display area DA.

An image is not displayed in the non-display area PA, and a driving circuit or a driving wire for driving the display area DA may be disposed in the non-display area PA.

The non-display area PA may include a first peripheral area PA1 located outside the display area DA and a second peripheral area PA2 including the driving unit 50, connection wires, and a bending area.

In the embodiment of FIG. 2, the first peripheral area PA1 is located on the third side of the display area DA, and the second peripheral area PA2 is located on the other side of the display area DA.

In one embodiment, the display panel DP may be assembled in a flat state with the display area DA and the non-display area PA facing the cover window WU.

However, the present inventive concept is not limited thereto.

A part of the non-display area PA of the display panel DP may be bent.

In this case, a part of the non-display area PA faces the rear surface of the display device 1000, so that the blocking area BA visible on the front surface of the display device 1000 can be reduced, and in FIG. 2, the second peripheral area (PA2) may be bent and positioned on the rear surface of the display area DA, and then assembled.

Also, the display area DA of the display panel DP may include a component area EA, and specifically, may include a first component area EA1 and a second component area EA2.

The first component area EA1 and the second component area EA2 may be at least partially surrounded by the display area DA.

The first component area EA1 and the second component area EA2 are illustrated as being spaced apart from each other, but the configuration of the first component area EA1 and the second component area EA2 are not limited thereto and may be connected at least in part.

The first component area EA1 and the second component area EA2 may be areas in which components using infrared light, visible light, or sound are disposed.

In the display area DA, a plurality of light emitting diodes and a plurality of pixel circuit units generating and transmitting a light emitting current are formed in each of the plurality of light emitting diodes.

Here, one light emitting diode and one pixel circuit part are referred to as a pixel PX.

In the display area DA, one pixel circuit unit and one light emitting diode are formed in a one-on-one arrangement.

The first component area EA1 may include a transmission portion through which light or/and sound may pass and a display portion including a plurality of pixels.

The transmission part is positioned between adjacent pixels, and is composed of a layer through which light or/and sound can pass.

The display unit may be formed to have one unit structure by combining a plurality of pixels, and a transmission unit may be positioned between adjacent unit structures.

Depending on the embodiment, a layer that does not transmit light, such as a light blocking layer, may overlap the first component area EA1.

The second component area EA2 includes an area composed of a transparent layer to allow light to pass through, no conductive layer or semiconductor layer is located, and a pixel definition layer including a light blocking material, a light blocking layer, and the like are provided in the second component area, and by including an opening in an area corresponding to the position corresponding to (EA2), it is possible to have a structure that does not block light.

A part of the second component area EA2 may include a portion where pixels and/or light emitting diodes are formed to block light.

Referring to FIG. 3, the display panel DP may further include a touch sensor TS in addition to the display area DA including the display pixels PX.

The display panel DP may be visually recognized by a user from the outside through the transmission area TA including the pixels PX, which are components for generating an image.

Also, the touch sensor TS may be positioned above the pixel PX and may detect an external input applied from the outside.

The touch sensor TS may detect an external input provided to the cover window WU.

Again, referring to FIG. 2, the second peripheral area PA2 may include a bending portion.

The display area DA and the first peripheral area PA1 may have a flat surface substantially parallel to a plane defined by the first and second directions DR1 and DR2, and the second peripheral area PA2 may be bent. One side of the second peripheral area PA2 may extend from the flat surface. The second peripheral area PA2 may have a flat surface, a bent surface, and a flat surface sequentially disposed along the second direction DR2.

As a result, at least a portion of the second peripheral area PA2 may be bent and assembled to be positioned on the rear side of the display area DA.

When assembled, at least a portion of the second peripheral area PA2 overlaps the display area DA in a plan view, so the blocking area BA of the display device 1000 may be reduced.

However, the present inventive concept is not limited thereto.

For example, the second peripheral area PA2 may not be bent.

The driving unit 50 may be mounted on the second peripheral area PA2, and may be mounted on the bent surface or located on one of both sides of the bent surface.

The driving unit 50 may be provided in the form of a chip.

The driving unit 50 may be electrically connected to the display area DA to transmit an electrical signal to the display area DA.

For example, the driving unit 50 may provide data signals to the pixels PX disposed in the display area DA.

Alternatively, the driving unit 50 may include a touch driving circuit, and may be electrically connected to the touch sensor TS disposed in the display area DA.

Meanwhile, the driving unit 50 may include various circuits in addition to the above circuits or may be designed to provide various electrical signals to the display area DA.

Meanwhile, the display device 1000 can have a pad part located at the end of the second peripheral area PA2, and can be electrically connected to a flexible printed circuit board (FPCB) including a driving chip by the pad part.

Here, the driving chip positioned on the flexible printed circuit board may include various driving circuits for driving the display device 1000 or connectors for supplying power.

According to embodiments, a rigid printed circuit board (PCB) may be used instead of a flexible printed circuit board.

The optical element ES may be disposed below the display panel DP.

The optical element ES may include a first optical element ES1 overlapping the first component area EA1 and a second optical element ES2 overlapping the second component area EA2.

The first optical element ES1 may use infrared light. In this case, a layer through which light does not transmit, such as a light blocking layer, may overlap the first component area EA1.

The first optical element ES1 may be an electronic element using light or sound.

For example, the first optical element ES1 may be a sensor that receives and uses light such as an infrared sensor, a sensor that outputs and detects light or sound to measure a distance or recognizes a fingerprint, or a small lamp that outputs light, and it may be a speaker or the like that outputs sound.

In the case of an electronic element using light, light of various wavelength bands such as visible light, infrared light, and ultraviolet light can be used.

The second optical element ES2 may include at least one of a camera, an IR camera, a dot projector, an IR illuminator, and a time-of-flight sensor (ToF sensor).

Referring to FIG. 3, the display device 1000 may include a display panel DP, a power supply module PM, a first electronic module EM1, and a second electronic module EM2.

The display panel DP, the power supply module PM, the first electronic module EM1, and the second electronic module EM2 may be electrically connected to each other.

FIG. 3 illustrates a display pixel and a touch sensor TS positioned in the display area DA among the components of the display panel DP.

The power supply module PM may supply power required for overall operation of the display device 1000.

The power supply module (PM) may include a conventional battery module.

The first electronic module EM1 and the second electronic module EM2 may include various functional modules for operating the display device 1000.

The first electronic module EM1 may be directly mounted on a motherboard electrically connected to the display panel DP, or may be mounted on a separate board and electrically connected to the motherboard through a connector (not shown).

The first electronic module EM1 may include a control module CM, a wireless communication module TM, an image input module IIM, an audio input module AIM, a memory MM, and/or an external interface IF.

Some of the modules may not be mounted on the motherboard, and may be electrically connected to the motherboard through a flexible printed circuit board connected thereto.

The control module CM may control overall operations of the display device 1000.

The control module (CM) may be a microprocessor.

For example, the control module CM activates or deactivates the display panel DP.

The control module CM may control other modules such as the image input module IIM or the audio input module AIM based on the touch signal received from the display panel DP.

The wireless communication module (TM) can transmit/receive radio signals with other terminals using a Bluetooth or Wi-Fi line.

The wireless communication module (TM) can transmit/receive voice signals using a general communication line.

The wireless communication module TM includes a transmitter TM1 for modulating and transmitting a signal to be transmitted, and a receiver TM2 for demodulating a received signal.

The image input module (IIM) may process the image signal and convert it into image data that can be displayed on the display panel (DP).

The audio input module (AIM) may receive an external sound signal by a microphone in a recording mode, a voice recognition mode, or the like and convert it into electrical voice data.

The external interface (IF) may serve as an interface connected to an external charger, a wired/wireless data port, a card socket (e.g., a memory card, an SIM/UIM card), and the like.

The second electronic module EM2 may include an acoustic output module (AOM), a luminescent module (LM), a light receiving module (LRM), and a camera module (CMM), among others, and at least some of these can be located on the back of the display panel (DP) as optical elements (ES), as in FIG. 1 and FIG. 2.

The optical element ES may include a light emitting module LM, a light receiving module LRM, and a camera module CMM.

Also, the second electronic module EM2 can be directly mounted on the motherboard, or mounted on a separate board and electrically connected to the display panel DP through connectors (not shown), or it can be electrically connected to the first electronic module EM1.

The acoustic output module AOM may convert audio data received from the wireless communication module TM or audio data stored in the memory MM and output the converted audio data to the outside.

The luminescent module LM may generate and output light.

The luminescent module LM may output infrared rays.

For example, the luminescent module LM may include an LED element.

For example, the light receiving module (LRM) may detect infrared rays.

The light receiving module LRM may be activated when infrared rays of a predetermined level or higher are detected.

The light receiving module LRM may include a CMOS sensor.

After the infrared light generated by the luminescent module LM is output, it is reflected by an external subject (e.g., the user's finger or face), and the reflected infrared light may be incident to the light receiving module LRM.

The camera module (CMM) may capture an external image.

In one embodiment, the optical element ES may additionally include a light detection sensor or a heat detection sensor.

The optical element ES may detect an external subject received through the front surface or provide a sound signal such as a voice to the outside through the front surface.

Also, the optical element ES may include a plurality of elements, and is not limited to one embodiment.

Again, referring to FIG. 2, the housing HM may be coupled to the cover window WU.

The cover window WU may be disposed on the front surface of the housing HM.

The housing HM may be coupled to the cover window WU to provide a predetermined accommodation space.

The display panel DP and the optical element ES may be accommodated in a predetermined accommodating space provided between the housing HM and the cover window WU.

The housing HM may include a material with relatively high rigidity.

For example, the housing HM may include a plurality of frames and/or plates made of glass, plastic, or metal, or a combination thereof.

The housing HM can stably protect components of the display device 1000 accommodated in the inner space from external impact.

Hereinafter, the structure of the display device 1000 according to another embodiment will be described with reference to FIG. 4.

FIG. 4 is a perspective view schematically illustrating a display device according to another embodiment.

A description of the same configuration as the above-mentioned components will be omitted.

FIG. 4 illustrates a foldable display device having a structure in which the display device 1000 is folded through a folding axis FAX.

Referring to FIG. 4, in one embodiment, the display device 1000 may be a foldable display device.

The display device 1000 may be folded outward or inward with respect to the folding axis FAX.

When folded outward with respect to the folding axis FAX, the display surface of the display device 1000 is positioned on the outside in the third direction DR3 so that images can be displayed in both directions.

When folded inward with respect to the folding axis FAX, the display surface may not be visually recognized from the outside.

In one embodiment, the display device 1000 may include a display area DA, a component area EA, and a non-display area PA.

The display area DA may be divided into a 1-1st display area DA1-1, a 1-2nd display area DA1-2, and a folding area FA.

The first display area (DA1-1) and the second display area (DA1-2) can be located on the left and right, respectively, based on (or centered around) the folding axis (FAX). The folding axis (FA) can be located between the first display area (DA1-1) and the second display area (DA1-2).

In this case, when folded outward with reference to the folding axis FAX, the 1-1st display area DA1-1 and the 1-2nd display area DA1-2 are positioned on both sides in the third direction DR3, and can display images in both directions.

In addition, when folded inward with respect to the folding axis FAX, the 1-1st display area DA1-1 and the 1-2nd display area DA1-2 may not be visually recognized from the outside.

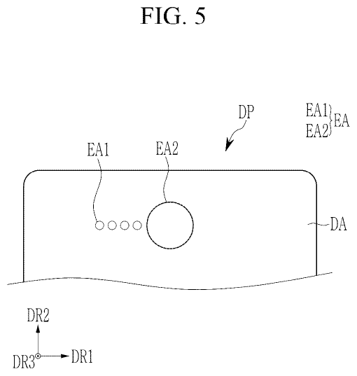

FIG. 5 is a top plan view illustrating an enlarged portion of a light emitting display device according to an embodiment.

FIG. 5 illustrates a portion of a light emitting display panel (DP) of a light emitting display device according to an embodiment, and is illustrated using a display panel for a mobile phone.

The light emitting display panel (DP) is located with a display area (DA) on the front and can include a component area (EA) on the front. Specifically, it may include the first component area (EA1) and the second component area (EA2).

Additionally, in the embodiment of FIG. 5, the first component area EA1 is located adjacent to the second component area EA2.

In the embodiment of FIG. 5, the first component area EA1 is positioned to the left of the second component area EA2.

The location and number of the first component area EA1 may vary according to embodiments.

In FIG. 5, the second optical element ES2 disposed in an area corresponding to the second component area EA2 may be a camera, and the first optical element ES1 disposed in an area corresponding to the first component area EA1 may be an optical sensor.

In the display area DA, a plurality of light emitting diodes and a plurality of pixel circuit units generating and transmitting a light emitting current are formed in each of the plurality of light emitting diodes.

Here, one light emitting diode and one pixel circuit part are referred to as a pixel PX.

In the display area DA, one pixel circuit unit and one light emitting diode are formed in a one-to-one arrangement.

The display area DA is hereinafter also referred to as a “normal display area.”

Although the structure of the light emitting display panel DP below the cutting line is not shown in FIG. 5, the display area DA may be located below the cutting line.

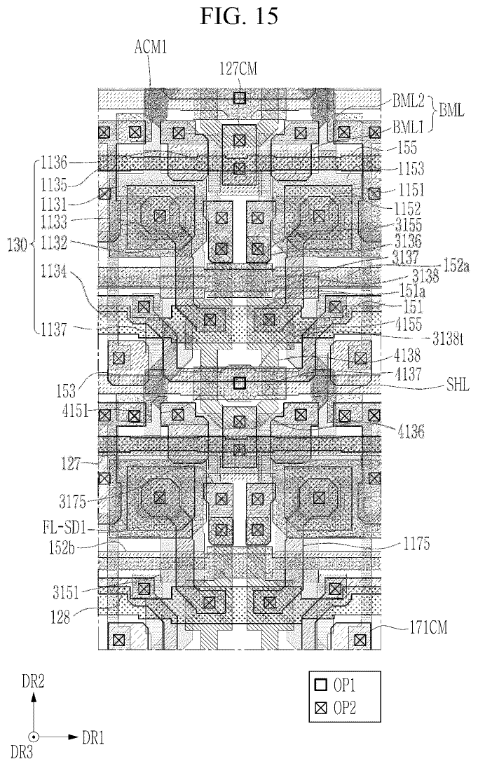

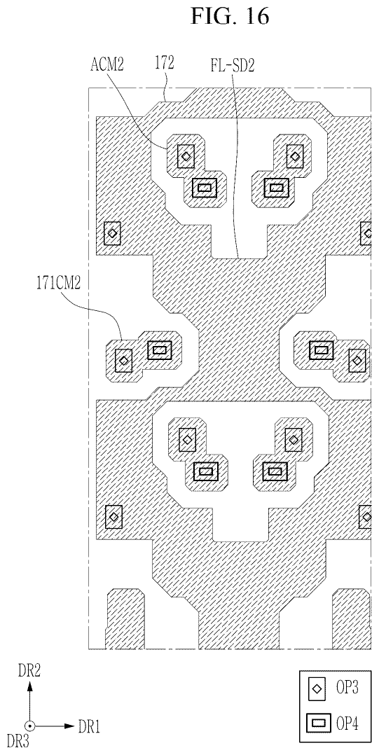

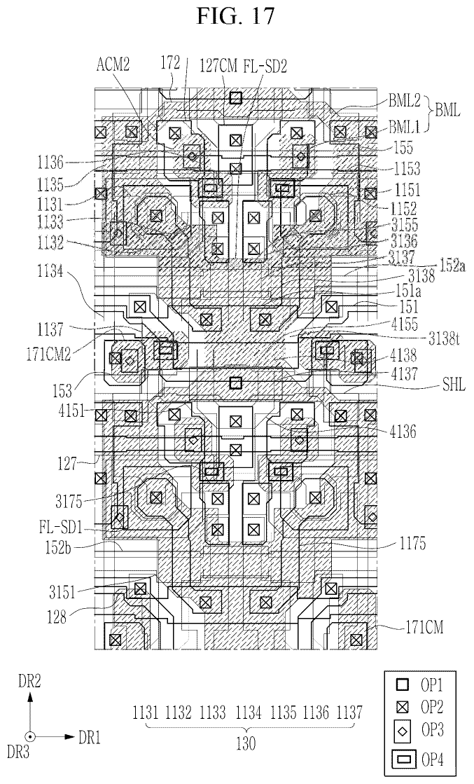

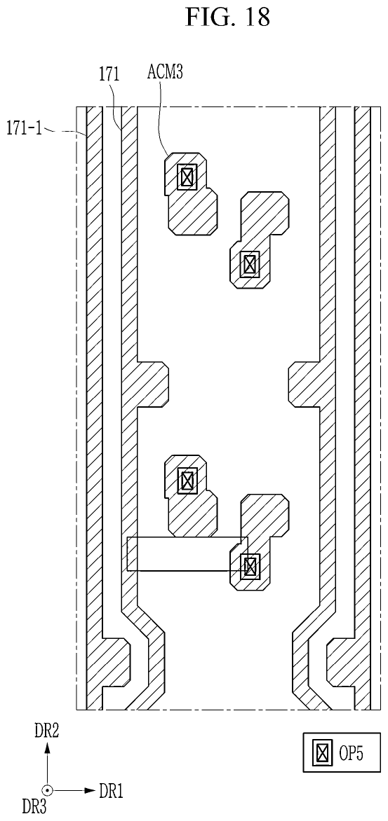

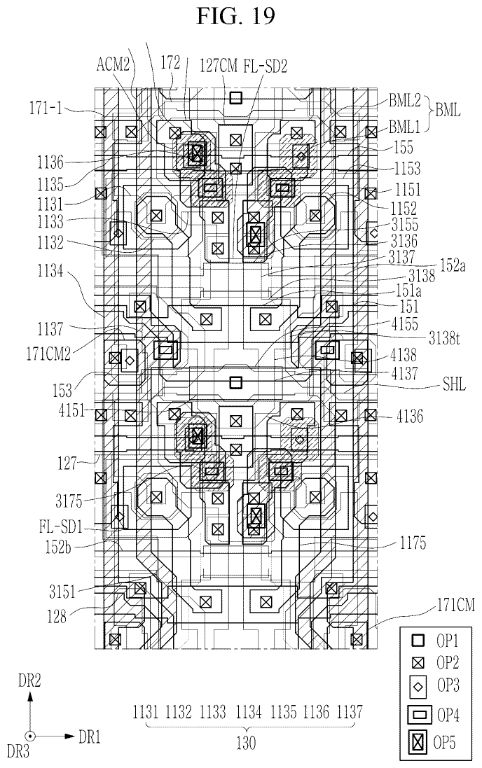

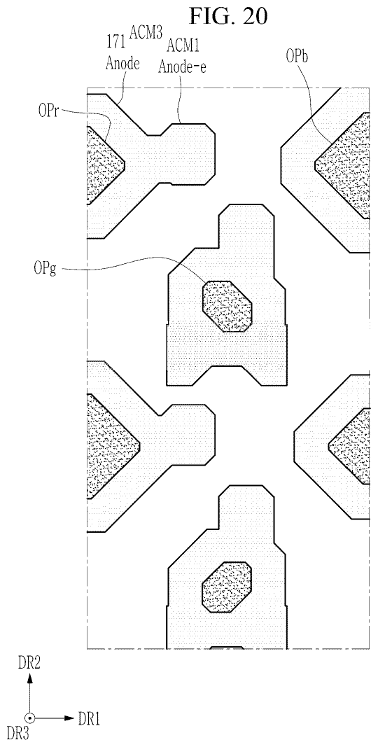

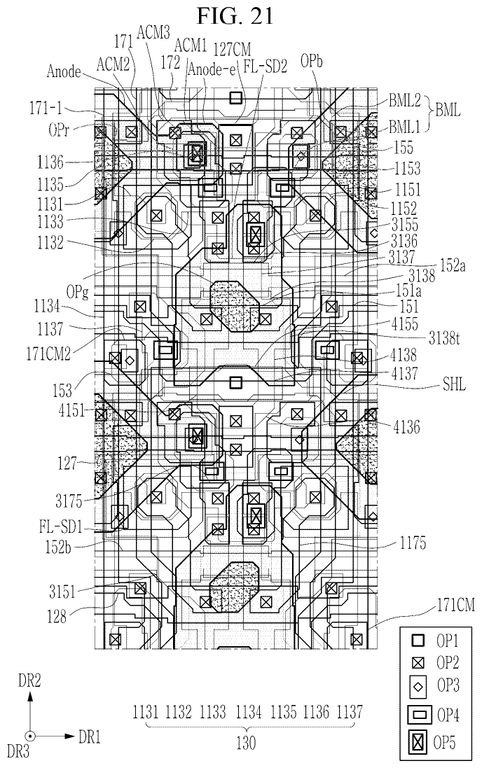

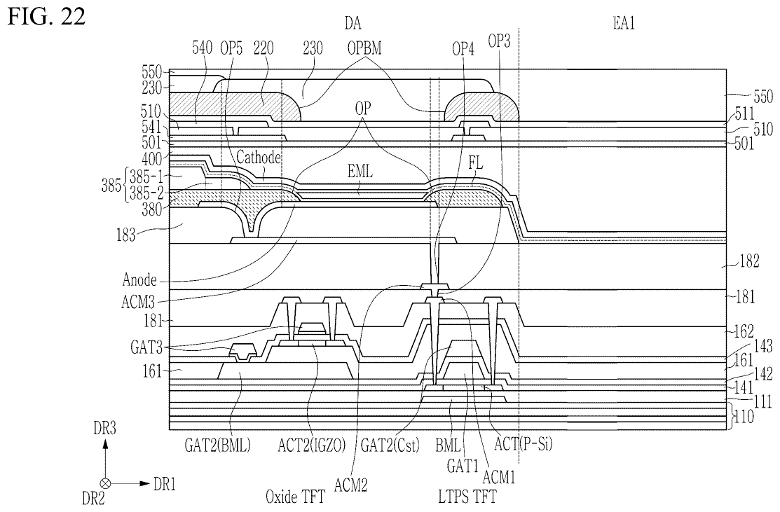

The first component area EA1 is composed of only a transparent layer through which light can pass, has no conductive layer or semiconductor layer, has a light transmitting area in the lower panel layer, and the pixel defining layer (see 380 in FIG. 22) in the upper panel layer, and openings (hereinafter referred to as additional openings) may be formed in the light blocking layer (refer to 220 in FIG. 22) and the color filter layer (refer to 230 in FIG. 22) at positions corresponding to the first component area EA1 so as not to block light.

Meanwhile, even if the light transmitting area is located in the lower panel layer, if there is no corresponding opening in the upper panel layer, it may be the display area DA instead of the first component area EA1.

Meanwhile, when the first optical element (ES1) corresponding to the first component area (EA1) uses infrared rays instead of visible light, the first component area (EA1) can overlap the light blocking layer (220) that blocks visible light.

The light emitting display panel DP according to the embodiment can be largely divided into a lower panel layer and an upper panel layer.

The lower panel layer is a portion where light emitting diodes constituting pixels and pixel circuits are located, and may even include an encapsulation layer (see 400 in FIG. 22) covering it.

That is, the lower panel layer includes an anode, a pixel defining layer (see 380 in FIG. 22), a light emitting layer (see EML in FIG. 22), and a spacer (see 385 in FIG. 22) from the substrate (see 110 in FIG. 22), a functional layer (see FL in FIG. 22), a cathode (see Cathode in FIG. 22), an insulating layer between the substrate and the anode, a semiconductor layer, and a conductive layer.

On the other hand, the upper panel layer is a part that is located on top of the lower panel layer, and it includes a sensing insulating layer (refer to 501, 510, 511 in FIG. 22), and a plurality of sensing electrodes (refer to 540, 541 in FIG. 22) that can detect touch, it may include a light blocking layer (refer to 220 in FIG. 22), a color filter (refer to 230 in FIG. 22), and a planarization layer (refer to 550 in FIG. 22).

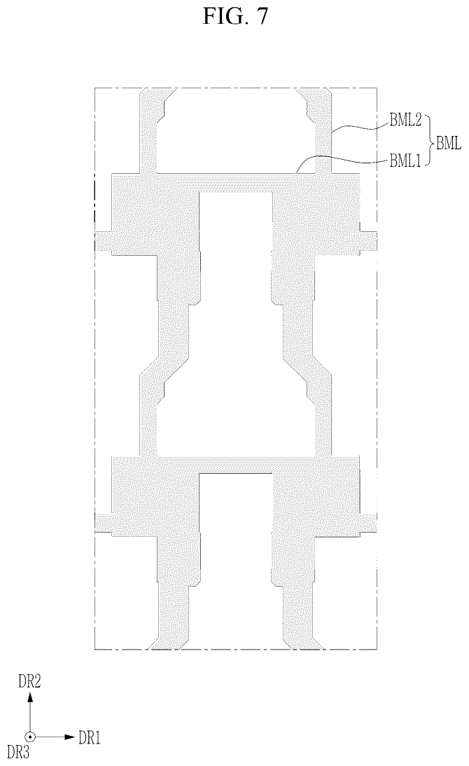

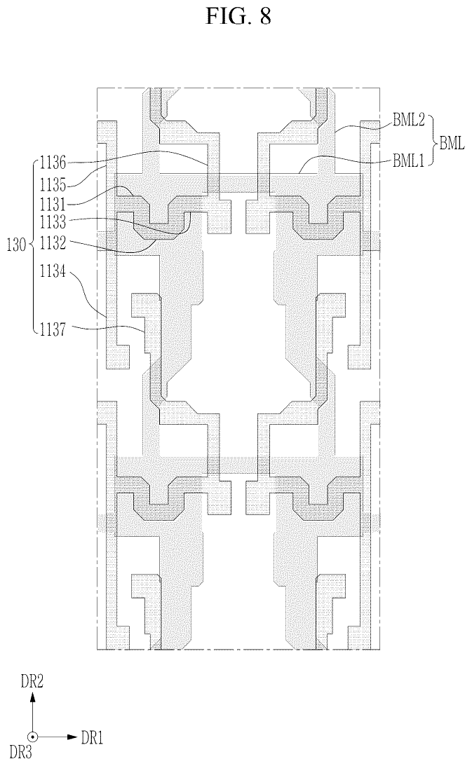

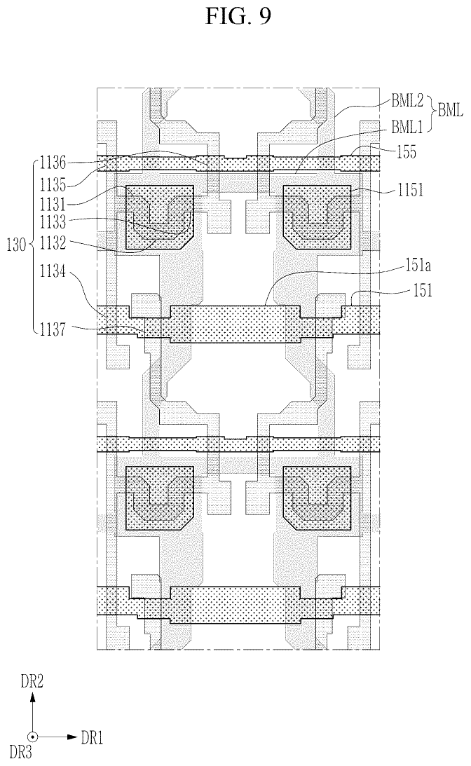

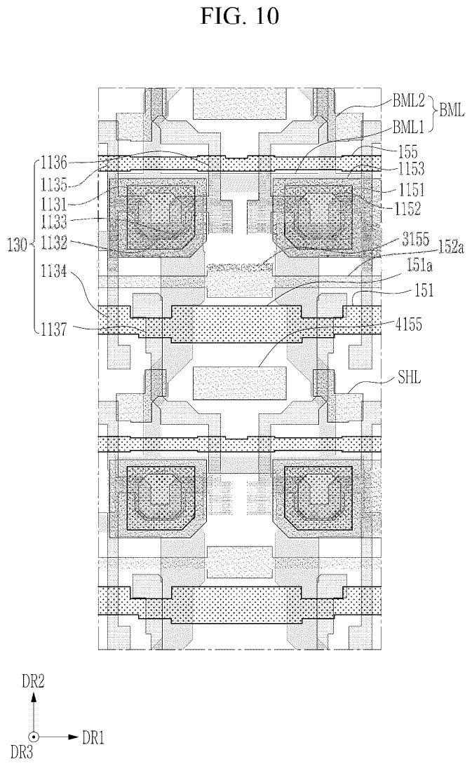

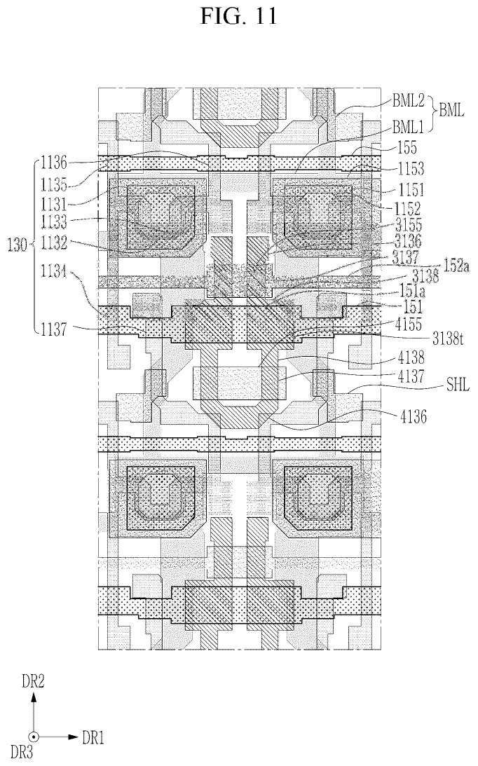

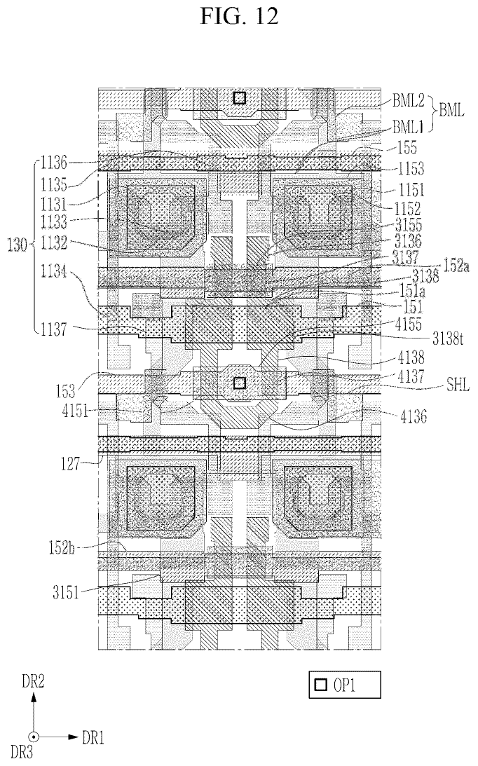

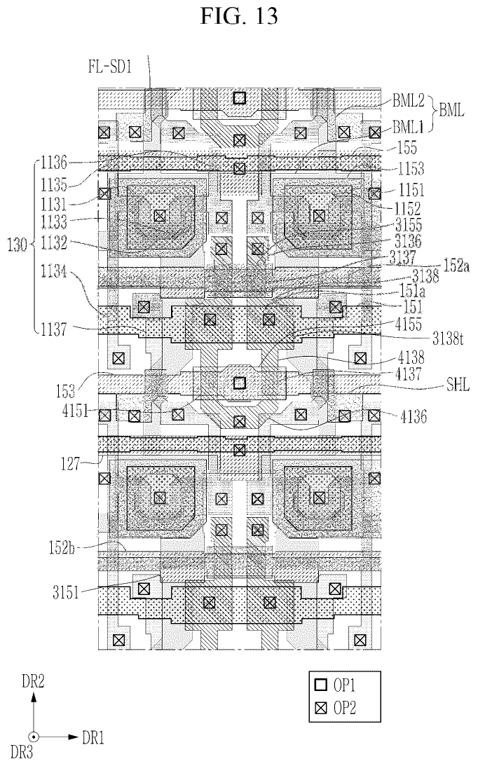

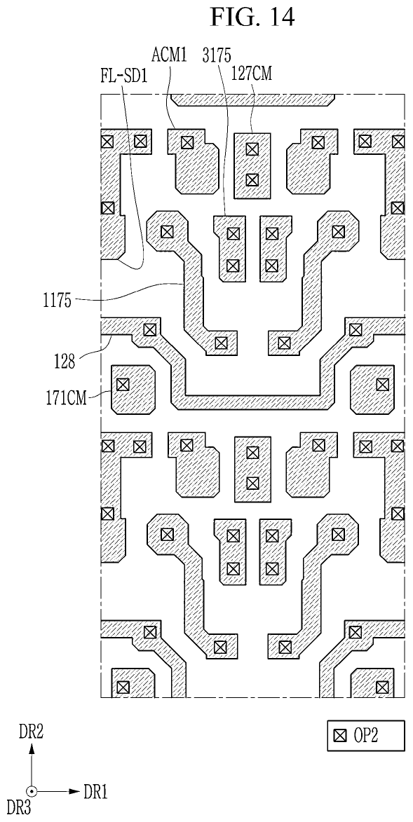

Meanwhile, the structure of the lower panel layer of the display area DA will be reviewed in FIG. 7 to FIG. 22.

Although not shown in FIG. 5, a peripheral area may be further positioned outside the display area DA.

In addition, although FIG. 5 shows a display panel for a mobile phone, the present embodiment can be applied to any display panel in which an optical element can be positioned on the rear surface of the display panel, or a flexible display device.

In the case of a foldable display among flexible display devices, the positions of the second component area EA2 and the first component area EA1 may be formed at positions different from those of FIG. 5.

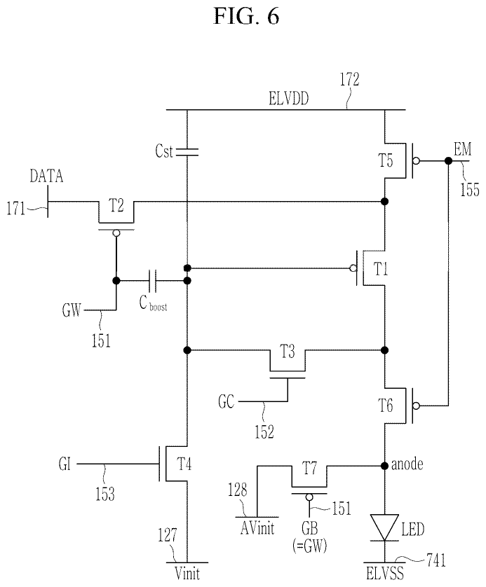

Hereinafter, a circuit structure of a pixel positioned on a lower panel layer of the light emitting display panel DP will be described in detail with reference to FIG. 6.

The following pixel structure may be a pixel structure of the display area DA, the first component area EA1, and/or the second component area EA2.

FIG. 6 is a circuit diagram of one pixel included in a light emitting display device according to an embodiment.

One pixel according to an embodiment includes a plurality of transistors T1, T2, T3, T4, T5, T6, and T7 connected to various wires 127, 128, 151, 152, 153, 155, 171, 172, and 741, a holding capacitor (Cst), a boost capacitor (C_{boost}), and a light emitting diode (LED).

Here, transistors and capacitors other than the light emitting diode (LED) constitute a pixel circuit unit.

Depending on embodiments, the boost capacitor C_{boost} may be omitted.

A plurality of wires 127, 128, 151, 152, 153, 155, 171, 172, and 741 are connected to one pixel PX.

The plurality of wires include a first initialization voltage line 127, a second initialization voltage line 128, a first scan line 151, a second scan line 152, an initialization control line 153, an emission control line 155, a data line 171, a driving voltage line 172, and a common voltage line 741.

The first scan line 151 is connected to a scan driving unit (not shown) to transmit the first scan signal GW to the second transistor T2 and the seventh transistor T7.

A voltage of opposite polarity to that applied to the first scan line 151 may be applied to the scan line 152 at the same time as the signal of the first scan line 151.

For example, when a voltage of negative polarity is applied to the first scan line 151, a voltage of positive polarity may be applied to the second scan line 152.

The second scan line 152 transfers the second scan signal GC to the third transistor T3.

The initialization control line 153 transfers the initialization control signal GI to the fourth transistor T4.

The emission control line 155 transmits the emission control signal EM to the fifth transistor T5 and the sixth transistor T6.

The data line 171 is a wire that transmits the data voltage DATA generated by the data driving unit (not shown), and accordingly, the size of the light emitting current transmitted to the light emitting diode (LED) is changed so that the light emitting diode (LED) emits light according to the light emitting current.

The driving voltage line 172 applies the driving voltage ELVDD.

The first initialization voltage line 127 transfers the first initialization voltage Vinit, and the second initialization voltage line 128 transfers the second initialization voltage A Vinit.

The common voltage line 741 applies the common voltage ELVSS to the cathode of the light emitting diode LED.

In this embodiment, voltages applied to the driving voltage line 172, the first and second initialization voltage lines 127 and 128, and the common voltage line 741 may be constant voltages.

The driving transistor T1 (also referred to as a first transistor) is a p-type transistor and has a silicon semiconductor as a semiconductor layer.

This transistor adjusts the amount of light emitting current output to the anode of the light emitting diode LED according to the level of the voltage of the gate electrode of the driving transistor T1—that is, the voltage stored in the storage capacitor Cst.

Since the brightness of the light emitting diode (LED) is adjusted according to the magnitude of the light emitting current output to the anode electrode of the light emitting diode (LED), the light emitting luminance of the light emitting diode (LED) can be adjusted according to the data voltage (DATA) applied to the pixel.

To this end, the first electrode of the driving transistor T1 receive the driving voltage ELVDD, and is connected to the driving voltage line 172 via the fifth transistor T5.

The first electrode of the driving transistor T1 is also connected to the second electrode of the second transistor T2 to receive the data voltage DATA.

Meanwhile, the second electrode of the driving transistor T1 outputs light emitting current to the light emitting diode LED, and is connected to the anode of the light emitting diode LED via the sixth transistor T6 (hereinafter referred to as an output control transistor).

The second electrode of the driving transistor T1 is also connected to the third transistor T3 to transfer the data voltage DATA applied to the first electrode to the third transistor T3.

Meanwhile, the gate electrode of the driving transistor T1 is connected to one electrode (hereinafter referred to as a “second storage electrode”) of the storage capacitor Cst.

Accordingly, the voltage of the gate electrode of the driving transistor T1 is changed according to the voltage stored in the storage capacitor Cst, and the emission current output from the driving transistor T1 is changed accordingly.

The storage capacitor Cst serves to keep the voltage of the gate electrode of the driving transistor T1 constant for one frame.

Meanwhile, the gate electrode of the driving transistor T1 can be connected to the third transistor T3, allowing the data voltage DATA applied to the first electrode of the driving transistor T1 to be transmitted to the gate electrode of the driving transistor T1 through the third transistor T3.

Meanwhile, the gate electrode of the driving transistor T1 may also be connected to the fourth transistor T4 to be initialized by receiving the first initialization voltage Vinit.

The second transistor T2 is a p-type transistor and has a silicon semiconductor as a semiconductor layer.

The second transistor T2 is a transistor that transmits the data voltage DATA to the first electrode of the driving transistor T1.

The gate electrode of the second transistor T2 is connected to the first scan line 151 and one electrode of the boost capacitor C_{boost} (hereinafter referred to as a “lower boost electrode”).

A first electrode of the second transistor T2 is connected to the data line 171.

The second electrode of the second transistor T2 is connected to the first electrode of the driving transistor T1.

When the second transistor T2 is turned on in response to the negative voltage of the first scan signal GW transmitted through the first scan line 151, the data voltage DATA transmitted through the data line 171, this is transmitted to the first electrode of the driving transistor T1, and the data voltage DATA is finally transferred to the gate electrode of the driving transistor T1 and stored in the storage capacitor Cst.

The transistor T3 is an n-type transistor, and has an oxide semiconductor as a semiconductor layer.

The third transistor T3 electrically connects the second electrode of the driving transistor T1 and the gate electrode of the driving transistor T1.

As a result, the data voltage DATA is compensated by the threshold voltage of the driving transistor T1 and then stored in the second storage electrode of the storage capacitor Cst.

The gate electrode of the third transistor T3 is connected to the second scan line 152, and the first electrode of the third transistor T3 is connected to the second electrode of the driving transistor T1.

The second electrode of the third transistor T3 includes the second storage electrode of the storage capacitor Cst, the gate electrode of the driving transistor T1, and the other electrode of the boost capacitor C_{boost} (hereinafter referred to as “upper boost electrode”), and it is connected.

The third transistor T3 is turned on in response to the voltage of the positive polarity among the second scan signals GC transmitted through the second scan line 152, and the gate electrode of the driving transistor T1 and the driving transistor T1 are turned on, the second electrode is connected, and the voltage applied to the gate electrode of the driving transistor T1 is transferred to the second storage electrode of the storage capacitor Cst and stored in the storage capacitor Cst.

The voltage stored in the storage capacitor Cst is the voltage of the gate electrode of the driving transistor T1 when the driving transistor T1 is turned off, so that the threshold voltage Vth of the driving transistor T1 is stored in a compensated state.

The transistor T4 is an n-type transistor, and has an oxide semiconductor as a semiconductor layer.

The fourth transistor T4 serves to initialize the gate electrode of the driving transistor T1 and the second storage electrode of the storage capacitor Cst.

The gate electrode of the fourth transistor T4 is connected to the initialization control line 153, and the first electrode of the fourth transistor T4 is connected to the first initialization voltage line 127.

The second electrode of the fourth transistor T4 is the second electrode of the third transistor T3, the second storage electrode of the storage capacitor Cst, the gate electrode of the driving transistor T1, and the upper portion of the boost capacitor C_{boost}, and it is connected to the boost electrode.

The fourth transistor T4 is turned on in response to a voltage of positive polarity among the initialization control signals GI transmitted through the initialization control line 153. The first initialization voltage Vinit is applied to the gate electrode of the driving transistor T1, the second storage electrode of the storage capacitor Cst, and the upper boost electrode of the boost capacitor C_{boost} to initialize the gate electrode of the driving transistor T1, the second storage electrode of the storage capacitor Cst, and the upper boost electrode of the boost capacitor C_{boost}.

The fifth transistor T5 and the sixth transistor T6 are p-type transistors, and have a silicon semiconductor as a semiconductor layer.

The fifth transistor T5 serves to transfer the driving voltage ELVDD to the driving transistor T1.

The gate electrode of the fifth transistor T5 is connected to the emission control line 155, the first electrode of the fifth transistor T5 is connected to the driving voltage line 172, and the first electrode of the fifth transistor T5 is connected to the driving voltage line 172. The second electrode is connected to the first electrode of the driving transistor T1.

The sixth transistor T6 serves to transfer the light emitting current output from the driving transistor T1 to the light emitting diode LED.

The gate electrode of the sixth transistor T6 is connected to the emission control line 155, the first electrode of the sixth transistor T6 is connected to the second electrode of the driving transistor T1, and the second electrode of the sixth transistor T6 is connected to the anode of the light emitting diode (LED).

The seventh transistor T7 is a p-type or n-type transistor, and may have a silicon semiconductor or an oxide semiconductor as a semiconductor layer. In the embodiment of FIG. 6, the seventh transistor T7 is a p-type transistor, and includes a silicon semiconductor.

The seventh transistor T7 serves to initialize the anode of the light emitting diode (LED).

The gate electrode of the seventh transistor T7 is connected to the first scan line 151, the first electrode of the seventh transistor T7 is connected to the anode of the light emitting diode (LED), and the second electrode of the seventh transistor T7 is connected to the second initialization voltage line 128.

Here, the gate electrode of the seventh transistor T7 is connected to the first scan line 151 of the previous pixel, and the same first scan line 151 as the gate electrode of the second transistor T2 belonging to the same pixel PX, but may be connected to the same first scan line 151 as the gate electrode of the second transistor T2 of the previous pixel PX

When the seventh transistor T7 is turned on by the negative voltage of the first scan line 151, the second initialization voltage A Vinit is applied to the anode of the light emitting diode (LED) to initialize it.

Meanwhile, the gate electrode of the seventh transistor T7 may be connected to a separate bypass control line through which the bypass signal GB is transmitted, and may be controlled by a separate wire from the first scan line 151.

Also, depending on embodiments, the second initialization voltage line 128 to which the second initialization voltage AVinit is applied may be the same as the first initialization voltage line 127 to which the first initialization voltage Vinit is applied.

It has been stated that one pixel PX includes seven transistors T1 to T7 and two capacitors (a storage capacitor Cst and a boost capacitor C_{boost}), but the present inventive concept is not limited thereto. The capacitor C_{boost} may be omitted.

Also, although the third and fourth transistors are formed of n-type transistors, only one of them may be formed of n-type transistors, or other transistors (e.g., the seventh transistor) may be formed of n-type transistors.

In the above, the circuit structure of the pixel PX formed in the display area DA has been reviewed through FIG. 6.

Hereinafter, the detailed planar structure and layered structure of the pixels PX formed in at least one location in the display area DA, the first component area EA1 and/or the second component area EA2 will be described through FIG. 7 to FIG. 22.

First, in FIG. 7 through FIG. 21, a planar structure will be mainly examined.

FIG. 7 to FIG. 21 are diagrams specifically illustrating the structure of each layer according to the manufacturing order of the lower panel layer in the light emitting display device according to an embodiment.

Referring to FIG. 7, a metal layer BML is positioned on the substrate (see 110 in FIG. 22).

The substrate 110 may include a rigid material such as glass, which does not bend, or may include a flexible material that can bend such as plastic or polyimide.

In the case of a flexible substrate, as shown in FIG. 22, a double-layered structure of polyimide and a barrier layer formed of an inorganic insulating material thereon may be formed.

The metal layer BML includes a plurality of expansion parts BML1 and a connection part BML2 connecting the plurality of expansion parts BML1 to each other.

The expansion part BML1 of the metal layer BML may be formed at a position overlapping a channel (refer to 1132 of FIG. 8) of the driving transistor T1 which includes first semiconductor layers in a plan view.

The metal layer (BML) is also referred to as a lower shielding layer, and may include a metal or metal alloy such as copper (Cu), molybdenum (Mo), aluminum (Al), and titanium (Ti), and may additionally include amorphous silicon, and may be composed of a single layer or multiple layers.

Referring to FIG. 22, a buffer layer 111 covering the substrate 110 and the metal layer BML is positioned on the substrate.

The buffer layer 111 serves to block impure elements from penetrating into the first semiconductor layer 130, and may be an inorganic insulating layer including silicon oxide (SiOₓ), silicon nitride (SᵢNₓ), or silicon oxynitride (SᵢONₓ).

On the buffer layer 111, as shown in FIG. 8, the first semiconductor layer 130 formed of a silicon semiconductor (e.g., polycrystalline semiconductor) is positioned.

The first semiconductor layer 130 includes the channel 1132 of the driving transistor T1, the first region 1131, and the second region 1133.

The first semiconductor layer 130 may constitute not only a channel 1132 of the driving transistor T1, but also the channel 1134 of the second transistor T2, the channel 1135 of the fifth transistor T5, and the channel of the sixth transistor T6 (1136), and a channel 1137 of the seventh transistor T7, and each channel has a first region and a second region having conductive characteristics by plasma treatment or doping on both sides of the first electrode of each transistor and serves as a second electrode.

The channel 1132 of the driving transistor T1 may be bent to have a U-shape in a plan view.

However, the shape of the channel 1132 of the driving transistor T1 is not limited thereto and may be variously changed.

For example, the channel 1132 of the driving transistor T1 may be bent in various other shapes such as an S shape or may be formed in a rod shape.

The first region 1131 and the second region 1133 of the driving transistor T1 may be positioned on both sides of the channel 1132 of the driving transistor T1.

The first region 1131 and the second region 1133 located in the first semiconductor layer have conductive characteristics by plasma treatment or doping, and serve as the first and second electrodes of the driving transistor T1.

In the portion of the first semiconductor layer 130 extending downward from the first region 1131 of the driving transistor T1, the channel 1134 of the second transistor T2 and a first region and a second region of the second transistor T2 disposed on both side of the channel 1134 are located.

The channel 1135 of the fifth transistor T5 and the first region and the second region positioned on both sides of the channel 1135 are located in the portion extending upward from the first region 1131 of the driving transistor T1.

The channel 1136 of the sixth transistor T6 and the first region and the second region positioned on both sides of the channel 1136 are located in a portion extending upward from the second region 1133 of the driving transistor T1.

A first region and a second region located on both sides of the channel 1137 and the channel 1137 of the seventh transistor T7 are bent through the channel 1136 of the sixth transistor T6 and further extended upward.

Referring to FIG. 22, a first gate insulating layer 141 is formed on the first semiconductor layer 130 including the channel 1132, the first region 1131, and the second region 1133 of the driving transistor T1.

The first gate insulating layer 141 may be an inorganic insulating layer including silicon oxide (SᵢOₓ), silicon nitride (SᵢNₓ), or silicon oxynitride (SᵢONₓ).

Referring to FIG. 9, a first gate conductive layer including the gate electrode 1151 of the driving transistor T1 may be positioned on the first gate insulating layer 141.

The first gate conductive layer may include not only the gate electrode (1151) of the driving transistor (T1), but also the gate electrodes of the second transistor (T2), fifth transistor (T5), sixth transistor (T6), and seventh transistor (T7).

The gate electrode 1151 of the driving transistor T1 may overlap the channel 1132 of the driving transistor T1.

The channel 1132 of the driving transistor T1 is covered by the gate electrode 1151 of the driving transistor T1.

The first gate conductive layer may further include the first scan line 151 and the emission control line 155.

The first scan line 151 and the emission control line 155 may extend substantially in a horizontal direction (hereinafter, also referred to as the first direction DR1).

The first scan line 151 may be connected to the gate electrode of the second transistor T2, and the first scan line 151 may be integrally formed with the gate electrode of the second transistor T2.

The first scan line 151 may be connected to or integrally formed with the gate electrode of the seventh transistor T7 of the next pixel.

The first scan line 151 may include a lower boost electrode 151a having an extended width, and overlap an upper boost electrode 3138t to be described later to form a boost capacitor C_{boost}.

Meanwhile, the light emitting control line 155 may be connected to the gate electrode of the fifth transistor T5 and the gate electrode of the sixth transistor T6, and the light emitting control line 155 and the fifth transistor T5 and the sixth transistor T6, and the gate electrode of (T6) may be formed integrally.

The first gate conductive layer may include a metal or metal alloy such as copper (Cu), molybdenum (Mo), aluminum (Al), or titanium (Ti), and may be composed of a single layer or multiple layers.

After forming the first gate conductive layer including the gate electrode 1151 of the driving transistor T1, a plasma treatment or doping process is performed, so that the first semiconductor layer 130 exposed and not covered by the first gate conductive layer 130 can be made conductive.

In other words, the first semiconductor layer 130 covered by the first gate conductive layer can form a channel without being conductive, and the portion of the first semiconductor layer 130 not covered by the first gate conductive layer can have the same characteristics as the conductive layer.

The transistor including the doped part may have p-type transistor characteristics, and the driving transistor T1, the second transistor T2, the fifth transistor T5, the sixth transistor T6, and the seventh transistor T7 can be p-type transistors.

Referring to FIG. 22, a second gate insulating layer 142 may be positioned on the first gate conductive layer including the gate electrode 1151 of the driving transistor T1 and the first gate insulating layer 141.

The second gate insulating layer 142 may be an inorganic insulating layer including silicon oxide (SᵢOₓ), silicon nitride (SᵢNₓ), or silicon oxynitride (SᵢONₓ).

Referring to FIG. 10, a second gate conductive layer which includes the first storage electrode 1153 of the maintenance capacitor Cst, the lower second scan line (152a) including the lower shielding layer 3155 of the third transistor T3, the lower shielding layer 4155 of the fourth transistor T4, and the shielding layer SHL can be located on the second gate insulation layer 142.

Here, the lower shielding layers (3155, 4155) can be located under the channels of the third transistor (T3) and the fourth transistor (T4), respectively, and can shield against light or electromagnetic interference provided to the channel from below.

In addition, the shielding layer SHL overlaps a portion of the first semiconductor layer 130 in a plan view.

Here, the portion overlapping the shielding layer (SHL) in the first semiconductor layer (130) may be located between the channel (1136) of the sixth transistor (T6) and the channel (1137) of the seventh transistor (T7) in a plan view.

Therefore, the portion of the first semiconductor layer 130 overlapping the shielding layer SHL in a plan view corresponds to the second region (or second electrode) of the sixth transistor T6 or the second region of the seventh transistor T7 corresponding to the first region (or first electrode) or located between the second region (or second electrode) of the sixth transistor T6 and the first region (or first electrode) of the seventh transistor T7.

Since the portion of the first semiconductor layer 130 overlapping the shielding layer SHL in a plan view is located on the path through which the output current output from the driving transistor T1 is transferred to the anode of the light emitting diode (LED), it is also referred to as the output current transfer region of the first semiconductor layer 130.

The first storage electrode 1153 overlaps the gate electrode 1151 of the driving transistor T1 to form a storage capacitor Cst.

An opening 1152 is formed in the first storage electrode 1153 of the storage capacitor Cst.

The opening 1152 of the first storage electrode 1153 of the storage capacitor Cst may overlap the gate electrode 1151 of the driving transistor T1.

The plurality of first storage electrodes 1153 may be connected to adjacent first storage electrodes 1153 in a horizontal direction (first direction, DR1).

Depending on embodiments, all of the plurality of first storage electrodes 1153 adjacent to each other in the horizontal direction (first direction, DR1) may be connected, but in the embodiment of FIG. 10, two adjacent first storage electrodes 1153 are connected. It is shown as a structure where only the structures connect to each other.

The lower second scan line 152a extends substantially in a horizontal direction (first direction, DR1) and may include the lower shielding layer 3155 of the third transistor T3 which is an expanded portion of the lower second scan line 152a.

Here, the lower shielding layer 3155 of the third transistor T3 may overlap the channel (see 3137 in FIG. 11) and the gate electrode (see 3151 in FIG. 12) of the third transistor T3.

Meanwhile, the lower shielding layer (4155) of the fourth transistor (T4) is formed in an island structure, and it can overlap the channel (refer to 4137 in FIG. 11) and gate electrode (refer to 4151 in FIG. 12) of the fourth transistor (T4).

The shielding layer SHL is disposed on both sides of the lower shielding layer 4155 of the fourth transistor T4 in the first direction DR1, and shields both sides of the lower shielding layer 4155 in the first direction DR1.

The second gate conductive layer GAT2 may include a metal or metal alloy such as copper (Cu), molybdenum (Mo), aluminum (Al), or titanium (Ti), and may be composed of a single layer or multiple layers.

Referring to FIG. 22, a first interlayer insulating layer 161 may be positioned on the second gate conductive layer which includes the first storage electrode 1153 of the storage capacitor Cst, the lower shielding layer 3155 of the third transistor T3 and the lower shielding layer 4155 of the fourth transistor T4.

The first interlayer insulating layer 161 may include an inorganic insulating layer including silicon oxide (SᵢOₓ), silicon nitride (SᵢNₓ), silicon oxynitride (SᵢONₓ), or the like, and depending on embodiments. The inorganic insulating layer may be formed to have a considerable thickness.

Referring to FIG. 11, an oxide semiconductor layer, which includes the channel 3137, the first area 3136, and the second area 3138 of the third transistor T3, and the channel 4137, the first region 4136, and the second region 4138 of the fourth transistor T4, can be located above the first interlayer insulating film 161.

Also, the oxide semiconductor layer may include an upper boost electrode 3138t of the capacitor C_{boost}.

The channel 3137, the first region 3136 and the second region 3138 of the third transistor T3, and the channel 4137, the first region 4136 and the second region 4138 of the fourth transistor T4 may be connected to each other to form one piece.

The first region 3136 and the second region 3138 of the third transistor T3 are positioned on both sides of the channel 3137 of the third transistor T3, and a first region 4136 and a second region 4138 of the fourth transistor T4 are positioned on both sides of the channel 4137 of the fourth transistor T4.

The second region 3138 of the third transistor T3 is connected to the second region 4138 of the fourth transistor T4.

The channel 3137 of the third transistor T3 overlaps the lower shielding layer 3155, and the channel 4137 of the fourth transistor T4 overlaps the lower shielding layer 4155.

An upper boost electrode 3138t of the capacitor C_{boost} having an expanded portion which is positioned between the second region 3138 of the third transistor T3 and the second region 4138 of the fourth transistor T4.

The upper boost electrode 3138t of the boost capacitor C_{boost} overlaps the lower boost electrode 151a of the boost capacitor C_{boost} positioned on the first gate conductive layer to form the boost capacitor C_{boost}.

Referring to FIG. 22, a third gate insulating layer 143 may be positioned on the oxide semiconductor layer which includes the channel 3137, the first region 3136 and the second region 3138 of the third transistor T3, the channel 4137, and the first region 4136, and the second region 4138 of the fourth transistor T4, and the upper boost electrode 3138t of the boost capacitor C_{boost}.

The third gate insulating layer 143 may be positioned on the entire surface of the oxide semiconductor layer and the first interlayer insulating layer 161.

Accordingly, the third gate insulating layer 143 is formed on the channel 3137, the first region 3136 and the second region 3138 of the third transistor T3, the channel 4137, the first region 4136 and the second region 4138 of the fourth transistor T4 and may cover top and side surfaces of the upper boost electrode 3138t of the boost capacitor C_{boost}.

However, the present embodiment is not limited thereto, and the third gate insulating layer 143 may not be located on the entire surface of the oxide semiconductor layer and the first interlayer insulating layer 161.

For example, the third gate insulating layer 143 may overlap the channel 3137, and may not overlap the first region 3136 and the second region 3138 of the third transistor T3.

Also, the third gate insulating layer 143 may overlap the channel 4137, and may not overlap the first region 4136 and the second region 4138 of the fourth transistor T4.

The third gate insulating layer 143 may include an inorganic insulating layer including silicon oxide (SᵢOₓ), silicon nitride (SᵢNₓ), or silicon oxynitride (SᵢONₓ).

Referring to FIG. 12, a third gate conductive layer including a gate electrode 3151 of the third transistor T3 and a gate electrode 4151 of the fourth transistor T4 may be positioned on the third gate insulating layer 143.

The gate electrode 3151 of the third transistor T3 may overlap the channel 3137 of the third transistor T3.

The gate electrode 3151 of the third transistor T3 may overlap the lower shielding layer 3155 of the third transistor T3.

The gate electrode 4151 of the fourth transistor T4 may overlap the channel 4137 of the fourth transistor T4.

The gate electrode 4151 of the fourth transistor T4 may overlap the lower shielding layer 4155 of the fourth transistor T4.

The third gate conductive layer may further include an upper second scan line 152b and the initialization control line 153.

The upper second scan line 152b and the initialization control line 153 may extend substantially in a horizontal direction (first direction, DR1).

The upper second scan line 152b includes the gate electrode 3151 of the third transistor T3, and forms the second scan line 152 together with the lower second scan line 152a.

The initialization control line 153 includes the gate electrode 4151 of the fourth transistor T4, and is electrically connected to the lower shielding layer 4155 of the second gate conductive layer through an opening OP1.

Here, the opening OP1 is formed in the third gate insulating layer 143 and the first interlayer insulating layer 161 to expose a portion of the lower shielding layer 4155 of the second gate conductive layer, and it is electrically connected to the initialization control line 153 located above.

In addition, the third gate conductive layer may further include the first initialization voltage line 127.

The first initialization voltage line 127 may extend substantially in a horizontal direction (first direction), and a first initialization voltage Vinit is applied.

The initialization control line 153 may overlap the shielding layer SHL and the lower shielding layer 4155 which are positioned in the second gate conductive layer.

First, the role of the shielding layer (SHL) overlapping the initialization control line 153 will be described below.

Even if the initialization control signal GI applied to the initialization control line 153 is varied, the fluctuation of the initialization control signal GI may not affect the output current transfer region which overlaps the initialization control line 153 and the shielding layer SHL in a plan view.

As a result, the output current delivered to the light emitting diode (LED) has no effect on the variation of the initialization control signal (GI), and display quality may be improved.

Meanwhile, the role of the lower shielding layer 4155 overlapping the initialization control line 153 is as follows.

Referring to FIG. 10 and FIG. 12, the second scan line 152 has a double-layer structure which includes a lower second scan line 152a and an upper second scan line 152b, but the initialization control line 153 only includes the initialization control line 153 as in FIG. 12 and have a single-layer structure.

As a result, since the channel 3137 of the third transistor T3 located between the second scan lines 152 of the double-layer structure is controlled by the second scan signal GC applied vertically in a cross-sectional view, the third transistor T3 can be more strongly controlled and properly operated, and leakage current may be avoided.

On the contrary, since the initialization control line 153 has a single-layer structure, the fourth transistor T4 connected to the initialization control line 153 may be weakly controlled compared to the third transistor T3, which may cause a leakage current.

However, in the present inventive concept, although the initialization control line 153 has a single-layer structure, the lower shielding layer 4155 is positioned under the channel 4137 of the fourth transistor T4, and the lower shielding layer 4155 is connected to the initialization control line 153 through an opening, the channel 4137 of the fourth transistor T4 may be affected by the initialization control signal GI from a top and a bottom of the channel 4137 of the fourth transistor T4 in a cross-sectional view, the fourth transistor (T4) is also more strongly controlled so that it operates properly and leakage current can be avoided.

As a result, each pixel can be appropriately controlled to provide improved display quality.

The third gate conductive layer GAT3 may include a metal or metal alloy such as copper (Cu), molybdenum (Mo), aluminum (Al), or titanium (Ti), and may be composed of a single layer or multiple layers.

After forming the third gate conductive layer including the gate electrode 3151 of the third transistor T3 and the gate electrode 4151 of the fourth transistor T4, portions of the oxide semiconductor layer not covered by the gate electrode 3151 of the third transistor T3 and the gate electrode 4151 of the fourth transistor T4 may have enhanced electrical conductivity through a plasma treatment or doping process. The oxide semiconductor layer covered by the gate electrode 3151 of the third transistor T3 and the gate electrode 4151 of the fourth transistor T4 may not have the enhanced electrical conductivity and may form a channel of the third transistor T3 and a channel of the fourth transistor T4.

The channel 3137 of the third transistor T3 may be positioned below the gate electrode 3151 to overlap the gate electrode 3151.

The first region 3136 and the second region 3138 of the third transistor T3 may not overlap the gate electrode 3151.

The channel 4137 of the fourth transistor T4 may be positioned below the gate electrode 4151 to overlap the gate electrode 4151.

The first region 4136 and the second region 4138 of the fourth transistor T4 may not overlap the gate electrode 4151.

The upper boost electrode 3138t may not overlap the third gate conductive layer.

A transistor including an oxide semiconductor layer may have characteristics of an n-type transistor.

Referring to FIG. 22, a second interlayer insulating layer 162 may be positioned on the third gate conductive layer including the gate electrode 3151 of the third transistor T3 and the gate electrode 4151 of the fourth transistor T4.

The second interlayer insulating layer 162 may have a single-layer or multi-layer structure.

The second interlayer insulating layer 162 may include an inorganic insulating material such as silicon nitride (SᵢNₓ), silicon oxide (SᵢOₓ), and silicon oxynitride (SᵢOₓN_{y}), and may include an organic material according to embodiments.

Referring to FIG. 13, an opening OP2 is formed in the second interlayer insulating layer 162 and/or the insulating layer positioned thereunder to expose the conductive layer or semiconductor layer positioned thereunder.

A part of the opening OP2 is at least one of the second interlayer insulating layer 162, the third gate insulating layer 143, the first interlayer insulating layer 161, the second gate insulating layer 142, and the first gate insulating layer 141, an opening may be formed in the first semiconductor layer 130, the first gate conductive layer, or the second gate conductive layer may be exposed, and the other opening OP2 may expose the second interlayer insulating layer 162 and/or the third gate conductive layer, and an opening may be formed in the insulating layer 143 to expose the oxide semiconductor layer or the third gate conductive layer.

According to embodiments, the entire opening OP2 may be formed by at least two processes using at least two masks.

A detailed structure of some openings (OP2) is as follows.

One of the openings OP2 can overlap at least a part of the gate electrode 1151 of the drive transistor T1, and can also be formed on the third gate insulating layer 143, the first interlayer insulating layer 161, and the second gate insulating layer 142.

In this case, one of the openings OP2 may overlap the opening 1152 of the first storage electrode 1153 and may be positioned inside the opening 1152 of the first storage electrode 1153.

One of the openings OP2 may at least partially overlap the boost capacitor C_{boost}, and may be further formed on the third gate insulating layer 143.

Another one of the openings OP2 overlaps at least a portion of the second region 1133 of the driving transistor T1, and the third gate insulating layer 143, the first interlayer insulating layer 161, the second gate insulating layer 142), and the first gate insulating layer 141.

Another one of the openings OP2 overlaps at least a portion of the first region 3136 of the third transistor T3, and may be formed on the third gate insulating layer 143.

Referring to FIG. 14 and FIG. 15, a first data conductive layer including a first connection electrode 1175 and a second connection electrode 3175 may be positioned on the second interlayer insulating layer 162.

FIG. 14 is a plan view which illustrates only the first data conductive layer and the opening OP2. FIG. 15 is a plan view showing all layers disposed below the first data conductive layer.

The first connection electrode 1175 may overlap the gate electrode 1151 of the driving transistor T1.

The first connection electrode 1175 may be connected to the gate electrode 1151 of the driving transistor T1 through the opening OP2 and the opening 1152 of the first storage electrode 1153.

The first connection electrode 1175 may overlap the boost capacitor C_{boost}.

The first connection electrode 1175 may be connected to the upper boost electrode 3138t of the boost capacitor C_{boost} through the opening OP2.

Accordingly, the gate electrode 1151 of the driving transistor T1 and the upper boost electrode 3138t of the boost capacitor C_{boost} may be connected by the first connection electrode 1175.

The gate electrode 1151 of the driving transistor T1 is connected to the second region 3138 of the third transistor T3, and the second region 4138 of the fourth transistor T4 by the first connection electrode 1175.

The second connection electrode 3175 may overlap the second region 1133 of the driving transistor T1.

The second connection electrode 3175 may be connected to the second region 1133 of the driving transistor T1 through the opening OP2.

The second connection electrode 3175 may overlap the first region 3136 of the third transistor T3.

The second connection electrode 3175 may be connected to the first region 3136 of the third transistor T3 through the opening OP2.

Accordingly, the second region 1133 of the driving transistor T1 and the first region 3136 of the third transistor T3 may be connected by the second connection electrode 3175.

The first data conductive layer may further include a second initialization voltage line 128.

The second initialization voltage line 128 extends substantially in a horizontal direction (first direction, DR1), and may have a part bent in a vertical direction (second direction, DR2).

The second initialization voltage line 128 is electrically connected to the first semiconductor layer 130 disposed adjacent to the channel 1137 of the seventh transistor T7 through the opening OP2, and the initialization voltage AVinit is transmitted to the seventh transistor T7.

The first data conductive layer may further include connection units 127 CM and 171 CM, a first anode connecting electrode ACM1 and a driving voltage connecting electrode FL-SD1.

The connection part 127 CM is connected to the first initialization voltage line 127 of the second gate conductive layer through the opening OP2, and is connected to a first region 4136 of the oxide semiconductor layer through the opening OP2, allowing the first initialization voltage Vinit flowing through the first initialization voltage line 127 to be transmitted to the fourth transistor T4 of the oxide semiconductor layer.

The connection part 171 CM is electrically connected to a portion disposed adjacent to the channel 1134 of the second transistor T2 in the first semiconductor layer 130 through the opening OP2, and is electrically connected to the second transistor T2.

The first anode connecting electrode ACM1 is electrically connected to an output current-carrying region disposed adjacent to the channel 1136 of the sixth transistor T6 in the first semiconductor layer 130 through the opening OP2 so as to be electrically connected to the sixth transistor T6.

The driving voltage connecting electrode FL-SD1 is electrically connected to a portion disposed adjacent to the channel 1135 of the fifth transistor T5 in the first semiconductor layer 130 and the first storage electrode 1153 through the openings OP2, and is electrically connected to the fifth transistor T5.

The driving voltage connecting electrode FL-SD1 is also connected to the shielding layer SHL through the opening OP2.

The first data conductive layer SD1 may include a metal or metal alloy such as aluminum (Al), copper (Cu), molybdenum (Mo), titanium (Ti), or the like, and may be composed of a single layer or multiple layers.

Referring to FIG. 22, a first organic layer 181 may be positioned on the first data conductive layer including the first connection electrode 1175 and the second connection electrode 3175.

The first organic layer 181 may be an organic insulating layer including an organic material, and the organic material includes at least one material selected from the group consisting of polyimide, polyamide, acrylic resin, benzocyclobutene, and phenol resin.

Referring to FIG. 16, FIG. 17, and FIG. 22, the lower organic layer opening OP3 is positioned in the first organic layer 181.

A second data conductive layer including a connection part 171CM2, the driving voltage line 172, and a second anode connecting electrode ACM2 may be positioned on the first organic layer 181.

A second organic layer 182 is positioned on the second data conductive layer, and an opening OP4 is formed in the second organic layer 182.

FIG. 16 is a plan view which illustrate only the second data conductive layer and the openings OP3 and OP4. FIG. 17 is a plan view which illustrates all the element disposed below the of the second data conductive layer.

In FIG. 16 and FIG. 17, the opening OP3 is disposed on the connecting portion 171 CM, the first anode connecting electrode ACM1, and the driving voltage connecting electrode FL-SD1 located in the first data conductive layer to expose them.

The second data conductive layer may include a connection part 171CM2, the driving voltage line 172, and the second anode connecting electrode ACM2.

The driving voltage line 172 extends substantially in a vertical direction (second direction, DR2), and may include a plurality of open areas.

The connection part 171CM2 and the second anode connecting electrode ACM2 may be positioned within the plurality of open areas of the driving voltage line 172.

The driving voltage line 172 is electrically connected to the fifth transistor T5, the first storage electrode 1153, and the shielding layer SHL through the drive voltage connecting electrode FL-SD1 of the first data conductive layer through the opening OP3.

As a result, the driving voltage ELVDD is applied to one electrode of the fifth transistor T5, the first storage electrode 1153, and the shielding layer SHL.

The connection part 171CM2 is connected to the connection part 171 CM of the first data conductive layer and the second transistor T2 through the opening OP3.

Also, the second anode connecting electrode ACM2 is electrically connected to the first anode connecting electrode ACM1 of the first data conductive layer through the opening OP3, and is electrically connected to the sixth transistor T6.

Referring to FIG. 16, the driving voltage line 172 may further include an opening portions FL-SD2 disposed in areas corresponding to portions where the second anode connecting electrode ACM2 and the connection part 171CM2 are formed.

The opening portions FL-SD2 are formed wide enough to flatten the anode located on the upper part.

The opening portions FL-SD2 positioned on the second data conductive layer may overlap an anode (refer to the anode of FIG. 20) of a light emitting diode in a plan view.

The structure of the lower part of the anode including the opening portions (FL-SD2) as described above and the organic films 181, 182, and 183 have a flattening characteristic so that the light reflected from the anode does not spread asymmetrically, as a result, the display quality can be improved by reducing the reflective color band caused by the color spreading (color separation) phenomenon caused by the reflected light.

The second data conductive layer SD2 may include a metal or metal alloy such as aluminum (Al), copper (Cu), molybdenum (Mo), or titanium (Ti), and may be composed of a single layer or multiple layers.

Referring to FIG. 22, a second organic layer 182 is positioned on the second data conductive layer.

The second organic layer 182 may be an organic insulating layer, and may include one or more materials selected from the group consisting of polyimide, polyamide, acrylic resin, benzocyclobutene, and phenol resin.

Depending on embodiments, the third organic layer 183 may be omitted.

Referring to FIG. 16, FIG. 17 and FIG. 22, an opening OP4 is formed in the second organic layer 182.

In FIG. 18, FIG. 19, and FIG. 22, a third data conductive layer including data lines 171 and 171-1 and a third anode connecting electrode ACM3 may be positioned on the second organic layer 182.

The third organic layer 183 is positioned on the third data conductive layer, and an opening OP5 for connecting an anode is formed on the third organic layer 183.

The third anode connecting electrode ACM3 is electrically connected to the anode through the anode connection opening OP5.

FIG. 18 is a plan view which only illustrates the third data conductive layer and the anode connection opening OP5. FIG. 19 is a plan view which illustrates all the element disposed below the third data conductive layer.

Referring to FIG. 16 and FIG. 17, the opening OP4 overlaps and exposes the connection part 171CM2 and the second anode connecting electrode ACM2 located in the second data conductive layer.

The third data conductive layer may include the data lines 171 and 171-1 and the third anode connecting electrode ACM3.

The data lines 171 and 171-1 may extend substantially in a vertical direction (second direction, DR2).

The data lines 171 and 171-1 are connected to the connection part 171CM2 of the second data conductive layer and the connection part 171 CM of the first data conductive layer and the second transistor T2 through the opening OP4.

Here, the data lines 171 and 171-1 may each have a structure connected to the second transistor T2 included in two adjacent pixels in the second direction DR2.

The third anode connecting electrode ACM3 is electrically connected to the second anode connecting electrode ACM2 of the second data conductive layer through the opening OP4 and thus electrically connected to the sixth transistor T6.

The third data conductive layer SD3 may include a metal or metal alloy such as aluminum (Al), copper (Cu), molybdenum (Mo), or titanium (Ti), and may be composed of a single layer or multiple layers.

Referring to FIG. 22, a third organic layer 183 is positioned on the third data conductive layer.

The third organic layer 183 may be an organic insulating layer, and may include one or more materials selected from the group consisting of polyimide, polyamide, acrylic resin, benzocyclobutene, and phenol resin.

An opening OP5 is formed in the third organic layer 183 and the anode and the third anode connecting electrode ACM3 are electrically connected to each other through the opening OP5.

The first organic layer 181, the second organic layer 182, and the third organic layer 183 are formed by stacking the organic layers and then planarizing the surface using a slit mask so that the anode located thereon can be formed more flatly.

The process of using such a slit mask may be formed every time each organic layer is stacked, and some organic layers may not be exposed to light with slit marks even after stacking.

Also, the slit marks used at this time have a pattern parallel to the first direction (DR1), that is, the horizontal direction, so they can more easily remove the steps of the organic film that occur due to the vertical direction pattern (second direction (DR2) formed on the first data conductive layer and/or the second data conductive layer.

Referring to FIG. 20 and FIG. 21, an anode is formed on the third organic layer 183.

The anode may further include an extension part Anode-e to form a contact hole to receive current from the pixel circuit through the anode connection opening OP5.

In. FIG. 20, FIG. 21, and FIG. 22, a pixel defining layer 380 is positioned on the anode, and openings OPr, OPg, and OPb of the pixel defining layer 380 are connected to the anode.

The openings OPr, OPg, OPb formed on the pixel definition layer 380 may include a red opening OPr that overlaps with the anode of the red light-emitting diode, a green opening OPg that overlaps with the anode of the green light emitting diode, and a blue opening OPb that overlaps with the anode of the blue light-emitting diode.

The extension part Anode-e of the anode is not exposed by the openings OPr, OPg, and OPb of the pixel defining layer 380, and has a structure overlapping the pixel defining layer 380 in a plan view.

As a result, the anode connection opening OP5 also has a structure overlapping the pixel defining layer 380 in a plan view.

Depending on the embodiment, the pixel defining layer 380 may have an opaque property, and in this case, may include a black pigment.

A planar structure in which the above structure is entirely laminated is shown in FIG. 21.

Referring to FIG. 22, since the opening OP5 for connecting the anode does not overlap the openings OPr, OPg, and OPb of the pixel defining layer 380 and the opening OPBM of the light blocking layer 220 in a plan view, the defining film 380 and the light blocking layer 220 overlap each other.

Also, some of the openings OP3 located in the first organic layer 181 overlap with the openings OPBM of the light blocking layer 220 in a plan view, and the remaining openings OP3 overlap with the light blocking layer 220 in a plan view.

Meanwhile, all of the openings OP3 may overlap the pixel defining layer 380 in a plan view.

In addition, in the present embodiment, the openings (OPr, OPg, OPb) of the pixel defining layer 380 are formed in areas corresponding to the opening portions (FL-SD2) of the second data conductive layer located below the anode, and thus the anodes may be formed flat.

As a result, external light is not asymmetrically reflected, so that the user cannot recognize the reflective color band.

As a result, degradation of display quality due to reflection of external light can be eliminated.

Based on the planar structure as described above, the overall cross-sectional structure of the light emitting display device will be explained through FIG. 22.

FIG. 22 is a cross-sectional view of a light emitting display device according to an embodiment.

FIG. 22 shows a stacked structure of the first component area EA1 in addition to the stacked structure of the display area DA.

The light emitting display device may include a lower panel layer and an upper panel layer, and the lower panel layer is a portion where light emitting diodes constituting pixels and pixel circuits are located, and may even include an encapsulation layer 400 covering them.

Here, the pixel circuit part includes the second organic layer 182 and the third organic layer 183. The light-emitting diode is disposed above the third organic layer 183.

A structure positioned above the encapsulation layer 400 may correspond to the upper panel layer.

Depending on embodiments, the third organic layer 183 may not be included. Referring to FIG. 22, the metal layer BML is positioned on the substrate 110.

The substrate 110 may include a rigid material, such as glass, which does not bend, or may include a flexible material that can bend, such as plastic or polyimide.

In the case of a flexible substrate, as shown in FIG. 22, a double-layered structure of polyimide and a barrier layer formed of an inorganic insulating material thereon may be formed.

The metal layer BML may be formed at a position overlapping the channel of the driving transistor T1 in a plan view, and is also referred to as a lower shielding layer.

The metal layer BML may include a metal or a metal alloy such as copper (Cu), molybdenum (Mo), aluminum (Al), or titanium (Ti).

A buffer layer 111 covering the substrate 110 and the metal layer BML is positioned on the substrate.

The buffer layer 111 may block the penetration of impure elements into the first semiconductor layer (ACT(P-Si)), and can be an inorganic insulating layer including silicon oxide (SᵢOₓ), silicon nitride (SᵢNₓ), silicon oxynitride (SᵢONₓ), etc.

A first semiconductor layer ACT1 (P-Si) formed of a silicon semiconductor (e.g., polycrystalline semiconductor (P-Si)) is positioned on the buffer layer 111.

The first semiconductor layer 130 includes a channel of the polycrystalline transistor (LTPS TFT) including the driving transistor T1 and first and second regions positioned on both sides of the channel.

Here, the polycrystalline transistor LTPS TFT may include not only the driving transistor T1, but also the second transistor T2, the fifth transistor T5, the sixth transistor T6, and the seventh transistor T7.

In addition, both sides of the channel of the first semiconductor layer (ACT1(P-Si)) may have conductivity by plasma treatment or doping to serve as the first and second electrodes of the transistor.

The first gate insulating layer 141 may be positioned on the first semiconductor layer ACT1(P-Si).

The first gate insulating layer 141 may be an inorganic insulating layer including silicon oxide (SᵢOₓ), silicon nitride (SᵢNₓ), or silicon oxynitride (SᵢONₓ).

A first gate conductive layer GAT1 including a gate electrode of the polycrystalline transistor LTPS TFT may be positioned on the first gate insulating layer 141.

In addition to the gate electrode of the polycrystalline transistor LTPS TFT, a first scan line or emission control line may be formed in the first gate conductive layer GAT1.

The first gate conductive layer may include a metal or metal alloy such as copper (Cu), molybdenum (Mo), aluminum (Al), or titanium (Ti), and may be composed of a single layer or multiple layers.

After forming the first gate conductive layer GAT1, a plasma treatment or a doping process may be performed to give the exposed region of the first semiconductor layer conductivity.

That is, the first semiconductor layer ACT1(P-Si) covered by the first gate conductive layer GAT1 does not have conductivity, and the first semiconductor layer ACT1 not covered by the first gate conductive layer GAT1 (P-Si)) may have conductivity similar to the conductive material.

A second gate insulating layer 142 may be positioned on the first gate conductive layer GAT1 and the first gate insulating layer 141.

The second gate insulating layer 142 may be an inorganic insulating layer including silicon oxide (SᵢOₓ), silicon nitride (SᵢNₓ), or silicon oxynitride (SᵢONₓ).

A second gate conductive layer GAT2, which includes a first electrode (GAT2(Cst)) of a storage capacitor Cst and a lower shielding layer (GAT2(BML)) of an oxide transistor Oxide TFT, can be located above the second gate insulating layer 142.

The bottom shielding layer (GAT2(BML)) of the Oxide TFT (Thin Film Transistor) is located under each channel of the Oxide TFT, it can serve to shield from light or electromagnetic interference provided from the bottom to the channel.

Meanwhile, one electrode GAT2(Cst) of the storage capacitor Cst overlaps the gate electrode GAT1 of the driving transistor T1 to form the storage capacitor Cst.

According to embodiments, the second gate conductive layer GAT2 may further include a scan line, a control line, or a voltage line.

The second gate conductive layer GAT2 may include a metal or metal alloy such as copper (Cu), molybdenum (Mo), aluminum (Al), or titanium (Ti), and may be composed of a single layer or multiple layers.

A first interlayer insulating layer 161 may be positioned on the second gate conductive layer GAT2.

The first interlayer insulating layer 161 may include an inorganic insulating layer including silicon oxide (SᵢOₓ), silicon nitride (SᵢNₓ), silicon oxynitride (SᵢONₓ), or the like, and depending on embodiments, an inorganic insulating material may be formed thickly.

An oxide semiconductor layer (ACT2(IGZO), also referred to as a second semiconductor layer), including a channel, a first region, and a second region of an oxide transistor (Oxide TFT) may be positioned on the first interlayer insulating layer 161.

A third gate insulating layer 143 may be positioned on the oxide semiconductor layer ACT2(IGZO).

The third gate insulating layer 143 may be positioned on the entire surface of the oxide semiconductor layer ACT2(IGZO) and the first interlayer insulating layer 161.

The third gate insulating layer 143 may include an inorganic insulating layer including silicon oxide (SᵢOₓ), silicon nitride (SᵢNₓ), or silicon oxynitride (SᵢONₓ).

A third gate conductive layer GAT3 including a gate electrode of an oxide transistor may be positioned on the third gate insulating layer 143.

A gate electrode of the oxide transistor may overlap the channel.

The third gate conductive layer GAT3 may further include scan lines or control lines.

The third gate conductive layer GAT3 may include a metal or metal alloy such as copper (Cu), molybdenum (Mo), aluminum (Al), or titanium (Ti), and may be composed of a single layer or multiple layers.

A second interlayer insulating layer 162 may be positioned on the third gate conductive layer GAT3.

The second interlayer insulating layer 162 may have a single-layer or multi-layer structure.

The second interlayer insulating layer 162 may include an inorganic insulating material such as silicon nitride (SᵢNₓ), silicon oxide (SᵢOₓ), and silicon nitride oxide (SᵢOₓN_{y}), and may include an organic material according to embodiments.

Above the second interlayer insulating layer (162), there can be a first data connecting layer (SD1) that includes a connecting electrode that can be connected to each of the first and second regions of the polycrystalline transistor (LTPS TFT) and oxide transistor (Oxide TFT).

The first data conductive layer SD1 may include a metal or metal alloy such as aluminum (Al), copper (Cu), molybdenum (Mo), titanium (Ti), or the like, and may be composed of a single layer or multiple layers.

A first organic layer 181 may be positioned on the first data conductive layer SD1.

The first organic layer (181) can be an organic insulating layer containing organic material, and the organic material can include one or more materials selected from the group consisting of polyimide, polyamide, acrylic resin, benzocyclobutene, and phenol resin.

A second data conductive layer including the second anode connecting electrode ACM2 may be positioned on the first organic layer 181.

The second data conductive layer may include a driving voltage line.

The second data conductive layer SD2 may include a metal or metal alloy such as aluminum (Al), copper (Cu), molybdenum (Mo), or titanium (Ti), and may be composed of a single layer or multiple layers.

A second organic layer 182 is positioned on the second data conductive layer, and the opening OP4 is formed in the second organic layer 182.

The second organic layer 182 may be an organic insulating layer, and may include one or more materials selected from the group consisting of polyimide, polyamide, acrylic resin, benzocyclobutene, and phenol resin.

A third data conductive layer including a third anode connecting electrode ACM3 may be positioned on the second organic layer 182.

The third data conductive layer may include data lines.

The second data conductive layer SD2 may include a metal or metal alloy such as aluminum (Al), copper (Cu), molybdenum (Mo), or titanium (Ti), and may be composed of a single layer or multiple layers.

A third organic layer 183 is positioned on the third data conductive layer, and an opening OP5 for connecting an anode is formed in the third organic layer 183.

The third anode connecting electrode ACM3 is electrically connected to the anode through the anode connection opening OP5.

The third organic layer 183 may be an organic insulating layer and may include one or more materials selected from the group consisting of polyimide, polyamide, acrylic resin, benzocyclobutene, and phenol resin.

A pixel defining layer 380 covering at least a portion of the anode while having an opening OP exposing the anode may be positioned on the anode.

The pixel defining layer 380 may be a black pixel defining layer formed of a black organic material to prevent externally applied light from being reflected back to the outside, or may be formed of a transparent organic material according to embodiments.

Therefore, according to embodiments, the pixel defining layer 380 may include a negative-type black organic material and may include a black pigment.

A spacer 385 is positioned on the pixel defining layer 380.

The spacer 385 may include a first portion 385-1 having a high height and a second portion 385-2 having a low height.

Unlike the pixel defining layer 380, the spacer 385 may be formed of a transparent organic insulating material.

According to an embodiment, the spacer 385 may be formed of a positive-type transparent organic material.

A functional layer FL and a cathode are sequentially formed on the anode, the spacer 385, and the pixel defining layer 380, and in the display area DA and the first component area EA1. The functional layer FL and the cathode may be located in the entire area.

The light emitting layer EML is positioned between the functional layers FL, and the light emitting layer EML may be positioned only within the opening OP of the pixel defining layer 380.

Hereinafter, the functional layer FL and the light emitting layer EML may be collectively referred to as an intermediate layer.

The functional layer FL may include at least one of an electron injection layer, an electron transport layer, a hole transport layer, and an auxiliary layer such as a hole injection layer, and the hole injection layer and the hole transport layer are disposed under the light emitting layer EML, and an electron transport layer and an electron injection layer may be located on the light emitting layer EML.

An encapsulation layer 400 is positioned on the cathode.

The encapsulation layer 400 includes at least one inorganic layer and at least one organic layer, and may have a triple-layer structure including a first inorganic encapsulation layer, an organic encapsulation layer, and a second inorganic encapsulation layer according to embodiments.

The encapsulation layer 400 may be for protecting the light emitting layer EML from moisture or oxygen that may be introduced from the outside.

Depending on the embodiment, the encapsulation layer 400 may include a structure in which an inorganic layer and an organic layer are sequentially stacked.

On the encapsulation layer 400, sensing insulating layers 501, 510, and 511, and a plurality of sensing electrodes 540 and 541 are positioned for touch sensing.

In the embodiment of FIG. 22, a touch may be sensed in a capacitive type using two sensing electrodes 540 and 541.

Specifically, a first sensing insulating layer 501 is formed on the encapsulation layer 400, and a plurality of sensing electrodes 540 and 541 are formed thereon.

The plurality of sensing electrodes 540 and 541 may be insulated with the second sensing insulating layer 510 interposed therebetween, and some may be electrically connected through openings located in the sensing insulating layer 510.

Here, the sensing electrodes 540 and 541 include metal or metal alloys such as aluminum (Al), copper (Cu), silver (Ag), gold (Au), molybdenum (Mo), titanium (Ti), and tantalum (Ta), and may be composed of a single layer or multiple layers.

A third sensing insulating layer 511 is formed on the sensing electrode 540.

A light blocking layer 220 and a color filter layer 230 are positioned on the upper sensing electrode 540 and the third sensing insulating layer 511.

The light blocking layer 220 may be positioned to overlap the sensing electrodes 540 and 541 in a plan view, and may be positioned not to overlap the anode in a plan view.

This is to prevent an anode capable of displaying an image from being covered by the light blocking layer 220 and the sensing electrodes 540 and 541.

The color filter layer 230 may be positioned on the third sensing insulating layer 511 and the light blocking layer 220.

The color filter layer 230 includes a red color filter that transmits red light, a green color filter that transmits green light, and a blue color filter that transmits blue light.

Each color filter layer 230 may be positioned to overlap the anode of the light emitting diode in a plan view.

Light emitted from the light emitting layer EML may be emitted while passing through a color filter and being changed to a corresponding color.

The light blocking layer 220 may be positioned between each color filter layer 230.

According to embodiments, the color filter layer 230 may be replaced with a color conversion layer or may further include a color conversion layer.

The color conversion layer may include quantum dots.

Also, depending on embodiments, a reflection control layer filling the opening OPBM of the light blocking layer 220 may be positioned instead of the color filter layer 230.

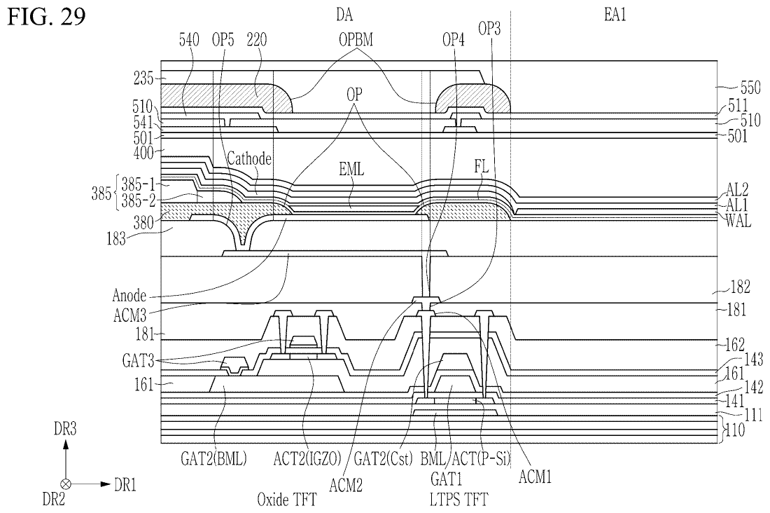

The reflection adjustment layer may have a structure covering the light blocking layer 220, which will be reviewed through FIG. 29.

A planarization layer 550 covering the color filter layer 230 may be positioned on the color filter layer 230.

In this embodiment, a polarizer may not be attached to the top of the planarization layer 550.

That is, the polarizing plate is attached to prevent external light from being reflected. In this embodiment, the opening (OPBM) of the light blocking layer 220 is formed in a specific structure to reduce the reflective color band problem in which external light is asymmetrically reflected, thus there is no need to include a polarizer. However, the polarizing plate may be attached to the planarization layer 550 to further reduce the light reflectance.

Meanwhile, in FIG. 22, a cross-sectional structure of the first component area EA1 is also shown.

The first component area (EA1) can be an area where the light sensor area (OPS) is located in the lower panel layer, and it can be an area where the pixel defining layer (380), the light blocking layer (220), and color filter layer (230) are not formed.

Depending on embodiments, the light transmission area of the second component area EA2 may have the same cross-sectional structure as the cross-section of the first component area EA1 of FIG. 22.

The first component area EA1 is composed of only a transparent layer so that light can pass therethrough, no conductive layer or semiconductor layer is located, and the pixel defining layer 380, the light blocking layer 220, and the color filter layer 230 are not included, an opening (hereinafter referred to as an additional opening) may be formed at a position corresponding to the optical sensor area OPS to have a structure that does not block light.

Specifically, based on FIG. 22, a stacked structure of the first component area EA1 according to an embodiment is as follows.

The buffer layer 111 as an inorganic insulating layer is positioned on the substrate 110, and the first gate insulating layer 141 and the second gate insulating layer 142 as inorganic insulating layers are sequentially positioned thereon.

In addition, the first interlayer insulating layer 161, the third gate insulating layer 143, and the second interlayer insulating layer 162, which are inorganic insulating layers, are sequentially stacked on the second gate insulating layer 142.

Only the first organic layer 181 among the organic insulating layers is stacked on the second interlayer insulating layer 162.

However, depending on embodiments, the second organic layer 182 and the third organic layer 183 may be stacked on the first organic layer 181.

The functional layer FL may be positioned on the third organic layer 183, and a cathode may be positioned thereon.

The stacked structure from the substrate 110 up to this point to the cathode may correspond to the optical sensor area OPS.

The encapsulation layer 400 is positioned on the cathode, and the sensing insulating layers 501, 510, and 511 are sequentially positioned thereon.

The encapsulation layer 400 may have a triple-layer structure including a first inorganic encapsulation layer, an organic encapsulation layer, and a second inorganic encapsulation layer.

In addition, all of the sensing insulating layers 501, 510, and 511 may be inorganic insulating layers.

Above the third sensing insulation layer (511), additional openings of the light blocking layer (220) and color filter layer (230) are located, and in the first component area (EA1), the light blocking layer (220) and color filter layer (230) are not formed.

An additional opening is also located in the pixel defining layer 380, so that the pixel defining layer 380 is not formed in the first component area EA1.

A planarization layer 550 may be positioned on the third sensing insulating layer 511 in the first component area EA1.

The first component area EA1 and the light sensor area OPS do not contain a metal layer BML, a first semiconductor layer ACT1, a first gate conductive layer GAT1, a second gate conductive layer GAT2, an oxide semiconductor layer ACT2, a third gate conductive layer GAT3, a first data conductive layer SD1, a second data conductive layer SD2, a third data conductive layer SD3, and an anode.

Also, the light emitting layer EML and the sensing electrodes 540 and 541 are not formed.

Additional openings are formed in the pixel defining layer 380, the light blocking layer 220, and the color filter layer 230 in the first component area EA1 and the photosensor area OPS to form the pixel defining layer 380, and the light blocking layer 220 and the color filter layer 230 may not be formed.

However, the light blocking layer 220 may be located in areas corresponding to the first component area EA1 and the light sensor area OPS when the optical sensor uses a wavelength other than visible light (for example, infrared rays), and the light blocking layer 220 is located on the front side.

In the above, the entire structure of the light emitting display device and its pixels has been described in detail.

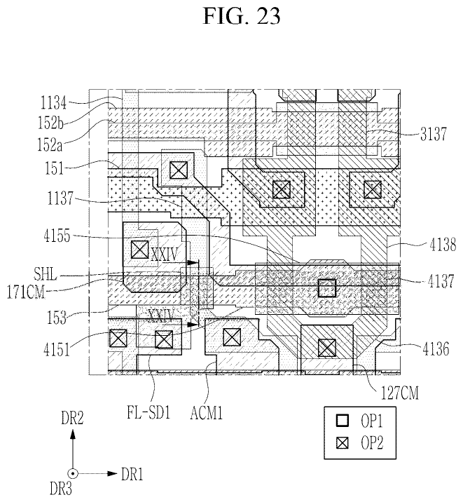

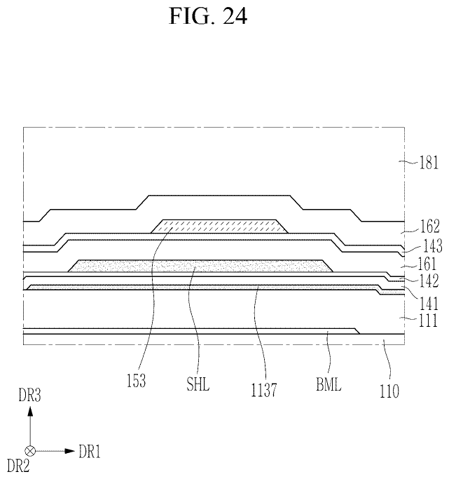

Hereinafter, the structure around the shielding layer (SHL) positioned on the second gate conductive layer and the role of the shielding layer (SHL) will be examined in detail through FIG. 23 and FIG. 24.

FIG. 23 is an enlarged plan view illustrating a vicinity of an initialization control line in a light emitting display device according to an embodiment, and FIG. 24 is a cross-sectional view taken along the XXIV-XXIV section line of FIG. 23.

FIG. 23 is an enlarged view of the shielding layer (SHL) and its surrounding structures among the pixels described in detail with reference to FIG. 7 to FIG. 21, including the first semiconductor layer, the first gate conductive layer, the second gate conductive layer, and the oxide semiconductor layer, the third gate conductive layer, and the first data conductive layer.

FIG. 24 is a cross-sectional view illustrating an overall stacked structure positioned above and below the shielding layer SHL.

The shielding layer SHL positioned on the second gate insulating layer is connected to the driving voltage connecting electrode FL-SD1 positioned on the first data conductive layer through the opening OP2.

The driving voltage connecting electrode (FL-SD1), as referred to in FIG. 16 and FIG. 17, is connected to the driving voltage line 172 located in the second data conductive layer through the opening (OP3), so the driving voltage (ELVDD) is delivered.

Therefore, the driving voltage ELVDD is also transmitted to the shielding layer SHL.

The shielding layer SHL does not overlap the first gate conductive layer in a plan view, and overlaps the output current passing region of the first semiconductor layer 130 and the initialization control line 153 of the third gate conductive layer in a plan view.

Here, the output current passing region of the first semiconductor layer 130 overlapping the shielding layer SHL in a plan view is a part of the first semiconductor layer 130, and referring to FIG. 11, the sixth transistor T6 is positioned between the second region (or second electrode) of the sixth transistor T6 and the first region (or first electrode) of the seventh transistor T7 area.

Referring to FIG. 24, the shielding layer SHL is positioned between the output current passing region of the first semiconductor layer 130 and the initialization control line 153 of the third gate conductive layer in a cross-sectional view, and the driving voltage ELVDD is constantly applied to the shielding layer SHL, it can play a role of shielding so that the change in voltage on one side is not transmitted to the other side.

Specifically, even if the initialization control signal GI applied to the initialization control line 153 varies, the output current transfer region of the first semiconductor layer 130 located under the shielding layer SHL may not be affected by the fluctuation of the initialization control signal GI due to the shielding layer (SHL).

As a result, the output current delivered to the light emitting diode (LED) has no effect on the variation of the initialization control signal (GI), and display quality may be improved.

Referring to FIG. 23, since the shielding layer (SHL) is formed on the second gate conductive layer in this embodiment, the initialization control line 153 may not have a double-layer structure including the second gate conductive layer and the third gate conductive layer but may have a single-layer structure only including the third gate conductive layer. Thus, the fourth transistor T4 connected to the initialization control line 153 is controlled relatively weakly, so leakage of current may occur.

However, in this embodiment, the lower shielding layer 4155 is formed as a second gate conductive layer under the channel 4137 of the fourth transistor T4, and is connected to the initialization control line 153 through the opening OP1, the fourth transistor T4 is also strongly controlled so as to operate correctly, and leakage of current may not occur.

That is, since the lower shielding layer 4155 is also connected to the initialization control line 153 through the opening OP1 and receives the initialization control signal GI, the channel 4137 of the fourth transistor T4 is disposed between the lower shielding layer 4155 and the initialization control line 153 in cross-sectional view. The initialization control signal GI is applied from the positioned initialization control line 153 and the lower shielding layer 4155 so that the fourth transistor T4 is more strongly controlled so that it operates correctly and leakage of current may not occur.

As a result, each pixel can be appropriately controlled to provide improved display quality.

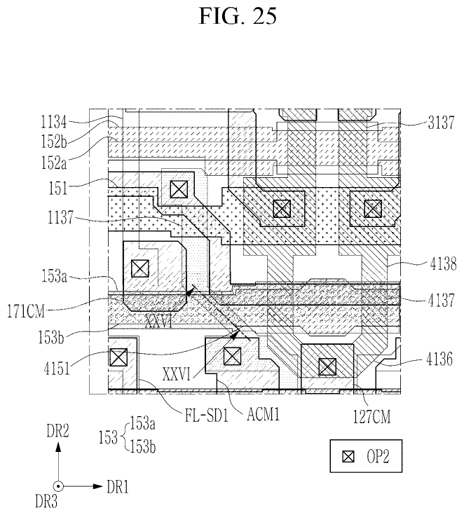

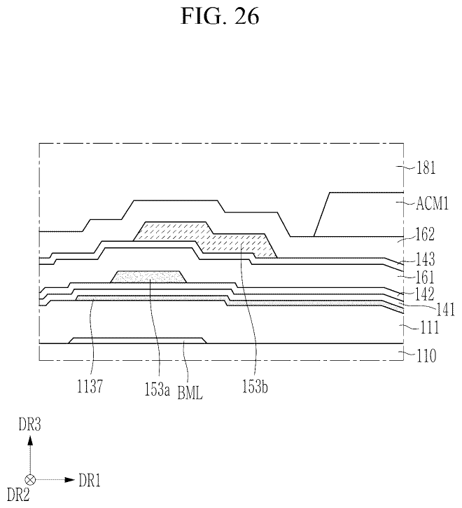

Meanwhile, hereinafter, the structure of the comparative example will be compared with reference to FIG. 25 and FIG. 26.

FIG. 25 is an enlarged plan view of the vicinity of an initialization control line in a light emitting display device according to a comparative example, and FIG. 26 is a cross-sectional view taken along the XXVI-XXVI section line of FIG. 25.

FIG. 25 is a plan view of a comparative example corresponding to FIG. 23, and FIG. 26 is a cross-sectional view taken along the XXVI-XXVI section line in FIG. 25.

Referring to FIG. 25, in the comparative example, the initialization control line 153 has a double-layered structure, with a lower initialization control line 153a positioned on the second gate insulating layer 142 and an upper initialization control line 153b positioned on the third gate insulating layer 143.

Since the lower initialization control line 153a is formed on the second gate insulating layer 142, a separate shielding layer SHL is not formed. A portion of the lower initialization control line 153a may function as the lower shielding layer.

The biggest difference between this embodiment and the comparative example is whether or not the shield layer SHL is located between the output current transfer region of the first semiconductor layer and the initialization control line.

Referring to FIG. 26, in the comparative example, since the initialization control signal GI is applied to the lower initialization control line 153a, when the initialization control signal GI is changed, the output current transfer area of the first semiconductor layer 130 is not shielded by the shield layer SHL, and as a result, a problem may occur in which the amount of the output current delivered to the light emitting diode (LED) is varied.

As a result, the luminance emitted by the light emitting diodes (LEDs) may change, resulting in deterioration in display quality.

In contrast, in the present embodiment, the shield layer SHL is disposed between the initialization control line 153 and the output current transfer region.

Therefore, since the layer to which the initialization control signal GI is applied is located farther from the output current transfer region of the first semiconductor layer 130 than in the comparative example, signal interference may be relatively small.

In addition, in the present embodiment, the shielding layer SHL which supplies the driving voltage ELVDD is located between the initialization control line 153 and the output current passing region of the first semiconductor layer 130, the fluctuation of the initialization control signal GI may not affect the output current.

As a result, since the output current delivered to the light emitting diode (LED) is not affected by the fluctuation of the initialization control signal (GI), display quality may be improved.

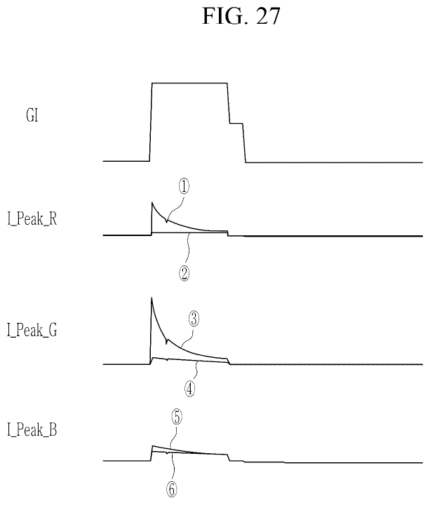

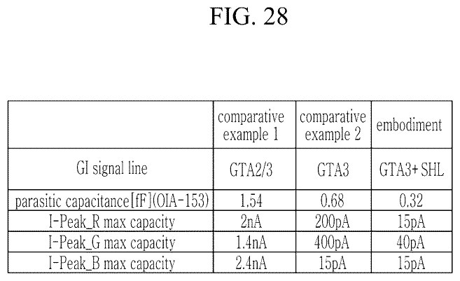

Hereinafter, a simulation result of a change in output current according to a change in the initialization control signal GI will be reviewed through FIG. 27 and FIG. 28.

FIG. 27 and FIG. 28 are views comparing and explaining differences in characteristics based on comparative examples and embodiments.

First, FIG. 27 shows the variation of the peak (I_Peak) of the output current when the voltage rises in the initialization control signal (GI) in the embodiments of FIG. 23 and FIG. 24, and the comparative examples of FIG. 25 and FIG. 26. The current peak (I_Peak) was simulated in pixels displaying red (R), green (G), and blue (B).

In FIG. 27, \textcircled{1}\textcircled{3}\textcircled{5} represent comparative examples, and \textcircled{2}\textcircled{4}\textcircled{6} represent embodiments.

Referring to FIG. 27, it can be seen that the fluctuation range of the peak (I_Peak_B) of the output current of the blue pixel is not high overall, but in the comparative example, the peak of the output current (I_Peak_R) of the red pixel and the peak (I_Peak_G) of the output current of the green pixel can confirm that a relatively large fluctuation range occurs.

A light emitting diode receiving such an output current may gradually change to a normal luminance after emitting strong light, which deteriorates display quality.

In contrast, in this embodiment, it can be confirmed that the fluctuation range of the peak output current (I_Peak) is not large in all colors, and it can also be confirmed that the fluctuation range of the peak output current of the blue pixel (I_Peak_B), the peak output current of the red pixel (I_Peak_R), and the peak output current of the green pixel (I_Peak_G) are almost the same.

In addition, since the variation range is not large, it is difficult for the user to recognize and detect it.

Therefore, in this embodiment, it can be confirmed that the display quality does not deteriorate due to the fluctuation of the output current.

FIG. 28 shows the above differences in a table.

FIG. 28 distinguishes between comparative example 1 and comparative example 2, where comparative example 1 corresponds to FIG. 25 and FIG. 26, and comparative example 2 is an example where the shielding layer (SHL) is not formed in FIG. 23 and FIG. 24 of this embodiment.

Referring to FIG. 28, parasitic capacitance between the output current passing region OIA of the first semiconductor layer 130 and the wiring 153 to which the initialization control signal GI is applied is described.

Compared to comparative example 1 and 2, it can be seen that the size of the parasitic capacitance of comparative example 2 is only about 44% and is reduced by about 66%.

However, it can be seen that a parasitic capacitance in this embodiment is only about 21% of the parasitic capacitance of comparative example 1, a reduction of about 79%.

Due to the difference in parasitic capacitance, the maximum change value of the peak (I_Peak_R) of the output current of the red pixel, the maximum change value of the peak (I_Peak_G) of the output current of the green pixel, and the maximum value of the peak (I_Peak_B) of the output current of the blue pixel, show that the variation value is very small in this embodiments.

As a result, the change in luminance of the light emitting diode, which may occur in the comparative example, does not appear in this example, and display quality can be improved.

In the foregoing, as shown in FIG. 22, the embodiment in which the color filter 230 is formed in the opening (OPBM) of the light blocking layer 220 has been mainly reviewed.

More specifically, a red color filter, a blue color filter, and a green color filter may be formed in the red opening OPBM, blue opening OPBM, and green opening OPBM of the light blocking layer 220, respectively.

However, a reflection control layer may be used instead of the color filter 230, and a laminated structure of an embodiment in which a reflection control layer 235 is applied instead of the color filter 230 will be described with reference to FIG. 29.

FIG. 29 is a cross-sectional view of a light emitting display device according to another embodiment.

FIG. 29 is a cross-sectional view corresponding to FIG. 22, and hereinafter, a description will be given focusing on a portion different from FIG. 22.

The reflection control layer 235 may be disposed on the light blocking layer 220.

The reflection control layer 235 may selectively absorb light having a wavelength of a partial band among light reflected inside the display device or light incident from the outside of the display device.

The reflection control layer 235 may fill the opening OPBM of the light blocking layer 220.

For example, the reflection control layer 235 absorbs a first wavelength range of 490 nm to 505 nm and a second wavelength range of 585 nm to 600 nm, so that light transmittance in the first wavelength range and the second wavelength range is 40% or less may be provided.

The reflection control layer 235 may absorb light having a wavelength outside of a red, green, or blue emission wavelength range emitted from the light emitting diode ED.

In this way, the reflection control layer 235 absorbs light of a wavelength that does not belong to the red, green, or blue wavelength range emitted from the light emitting diode, thereby preventing or minimizing the decrease in luminance of the display device and simultaneously displaying the display, so it is possible to prevent or minimize a decrease in luminous efficiency of the device and improve visibility.

In one embodiment, the reflection control layer 235 may include an organic material layer including a dye, a pigment, or a combination thereof.

The reflection adjusting layer 235 includes a tetra aza porphyrin (TAP)-based compound, a porphyrin-based compound, a metal porphyrin-based compound, an oxazine-based compound, and squarylium-based compounds, triarylmethane-based compounds, polymethine-based compounds, anthraquinone-based compounds, phthalocyanine-based compounds, azo-based compounds, perylene-based compounds, xanthene-based compounds, diimmonium-based compounds, dipyrromethene-based compounds, cyanine-based compounds, and combinations thereof.

In one embodiment, reflectance measured in a specular component included (SCI) mode on the surface of the reflection adjustment layer 235 may be 10% or less.

That is, the reflection control layer may improve visibility by absorbing external light reflection of the display device.

In one embodiment, the reflection control layer 235 may have a transmittance of about 64% to about 72%.

Transmittance of the reflection control layer 235 may be adjusted according to the amount of pigment and/or dye included in the reflection control layer 235.

Depending on the embodiment, the reflection control layer 235 may not be located in the first component area EA1.

Also, in an embodiment including the reflection control layer 235, a capping layer AL1 and a low-reflection layer AL2 may be additionally formed between the cathode and the encapsulation layer 400.

The capping layer AL1 may serve to improve light emitting efficiency of the light emitting diode by the principle of constructive interference.

The capping layer AL1 may include, for example, a material having a refractive index of 1.6 or higher for light having a wavelength of 589 nm.

The capping layer AL1 may be an organic capping layer including an organic material, an inorganic capping layer including an inorganic material, or a composite capping layer including an organic material and an inorganic material.

For example, the capping layer AL1 may include carbocyclic compounds, heterocyclic compounds, amine group-containing compounds, porphine derivatives, phthalocyanine derivatives, naphthalocyanine derivatives, and alkali metal complexes, an alkaline earth metal complex, or any combination thereof.

Carbocyclic compounds, heterocyclic compounds and amine group-containing compounds may be optionally substituted with substituents including O, N, S, Se, Si, F, Cl, Br, I, or any combination thereof.

The low-reflection layer AL2 may be disposed on the capping layer AL1.

The low-reflection layer AL2 may overlap the front surface of the substrate SUB.

The low-reflection layer AL2 may include an inorganic material having low reflectivity, and may include a metal or metal oxide in one embodiment.

When the low-reflection layer AL2 includes a metal, for example, ytterbium (Yb), bismuth (Bi), cobalt (Co), molybdenum (Mo), titanium (Ti), zirconium (Zr), aluminum (Al), chromium (Cr), niobium (Nb), platinum (Pt), tungsten (W), indium (In), tin (Sn), iron (Fe), nickel (Ni), tantalum (Ta), manganese (Mn), it may include zinc (Zn), germanium (Ge), silver (Ag), magnesium (Mg), gold (Au), copper (Cu), calcium (Ca), or a combination thereof.

Further, when the low-reflection layer AL2 includes a metal oxide, for example, SiO₂, TiO₂, ZrO₂, Ta₂O₅, HfO₂, Al₂O₃, ZnO, Y₂O₃, BeO, MgO, PbO₂, WO₃, SiNx, LiF, CaF₂, MgF₂, CdS or a combination thereof may be included as one constituent compound.

In one embodiment, the absorption coefficient (k) of the inorganic material included in the low-reflection layer AL2 may be 4.0 or less and 0.5 or more (0.5≤k≤4.0).

In addition, the inorganic material included in the low-reflection layer AL2 may have a refractive index n of 1 or more (n≥1.0).

The low-reflection layer AL2 induces destructive interference between light incident to the inside of the display device and light reflected from a metal disposed under the low-reflection layer AL2, thereby reducing external light reflectance.

Therefore, display quality and visibility of the display device may be improved by reducing the external light reflectance of the display device through the low-reflection layer AL2.

Depending on the embodiment, the capping layer AL1 may be omitted so that the low-reflection layer AL2 may come into contact with the cathode.

The encapsulation layer 400 is positioned on the low-reflection layer AL2, and other structures are the same as those of FIG. 22, so descriptions are omitted.

Meanwhile, the cathode formed in the display area may not be formed in the first component area EA1, and in the embodiment of FIG. 29, the low-adhesion layer (WAL) may be located.

The low-adhesion layer WAL may be positioned on the functional layer FL in the first component area EA1.

The low-adhesion layer (WAL) is a material with weak adhesiveness, and according to the embodiment, the upper surface of the low-adhesion layer (WAL) may not have a cathode arranged thereon, or it may include a material that has a characteristic of being a very thin film on the cathode.

For example, the low-adhesion layer (WAL) is 8-quinolinolato lithium (Liq; [8-Quinolinolato Lithium]), N,N-diphenyl-N,N-bis(9-phenyl-9H-carbazol-3-yl) biphenyl-4,4′-diamine (N,N-diphenyl-N,N-bis (9-phenyl-9H-carbazol-3-yl) biphenyl-4,4′-diamine; HT01), N (diphenyl-4-yl) 9,9-dimethyl-N-(4 (9-phenyl-9H-carbazol-3-yl) phenyl)-9H-fluoren-2-amine (N (diphenyl-4-yl) 9,9-dimethyl-N-(4(9-phenyl-9H-carbazol-3-yl)phenyl)-9H-fluorene-2-amine; HT211), 2-(4-(9,10-di(naphthalene)-2-yl) anthracene-2-yl) phenyl)-1-phenyl-1H-benzo-[D] imidazole (2-(4-(9,10-di (naphthalene-2-yl) anthracene-2-yl) phenyl)-1-phenyl-1H-benzo-[D]imidazole; LG201).

Although the present specification has shown and described an embodiment in which the low-adhesion layer WAL is located in the first component area EA1, it may be removed through a laser process or the like in other embodiments.

In this case, the laser process may be a laser process performed on a cathode.

In the first component area EA1, the capping layer AL1, the low-reflection layer AL2, and the encapsulation layer 400 may be disposed on the low-adhesion layer WAL.

Although the embodiments have been described in detail above, the scope of the present inventive concept is not limited thereto, and various modifications and improvements made by those skilled in the art using the basic concepts of the present inventive concept defined in the following claims are also included in the scope of the present inventive concept.

What is claimed is:

1. A light emitting display device, comprising:
a first semiconductor layer disposed on a substrate and including a channel of a driving transistor, a channel of a sixth transistor, and an output current transfer region disposed on one side of the channel of the sixth transistor;
a first gate conductive layer disposed on the first semiconductor layer and including a gate electrode of the driving transistor overlapping the channel of the driving transistor and an emission control line overlapping the channel of the sixth transistor;
a second gate conductive layer disposed on the first gate conductive layer and including a first storage electrode overlapping the gate electrode of the driving transistor and a shielding layer overlapping the output current passing region in a plan view;
a second semiconductor layer disposed on the second gate conductive layer and including a channel of a fourth transistor;
a third gate conductive layer disposed on the second semiconductor layer and including an initialization control line overlapping the channel of the fourth transistor;
a first data conductive layer disposed on the third gate conductive layer and including a driving voltage connecting electrode and a first anode connecting electrode electrically connected to the output current passing region disposed on one side of the channel of the sixth transistor;
a first organic layer covering the first data conductive layer;
a second data conductive layer disposed on the first organic layer and including a second anode connecting electrode electrically connected to the first anode connecting electrode and a driving voltage line;
second organic layers disposed on the second data conductive layer; and
an anode disposed on the second organic layer and electrically connected to the second anode connecting electrode,
wherein the initialization control line overlaps the output current passing region and the shielding layer disposed on one side of the channel of the sixth transistor in a plan view, and
wherein the shielding layer is connected to the driving voltage line through the driving voltage connecting electrode.

2. The light emitting display device of claim 1, wherein:
the second gate conductive layer further includes a lower shielding layer of the fourth transistor, and
the lower shielding layer of the fourth transistor is electrically connected to the initialization control line and overlaps the channel of the fourth transistor in a plan view.

3. The light emitting display device of claim 2, wherein:
the second gate conductive layer further includes a lower second scan line,
the second semiconductor layer further includes a channel of a third transistor,
the third gate conductive layer further includes an upper second scan line,
the channel of the third transistor overlaps the lower second scan line and the upper second scan line in a plan view; and
the same signal is applied to the lower second scan line and the upper second scan line.

4. The light emitting display device of claim 2, wherein:
the first semiconductor layer further includes a channel of a seventh transistor,
one end of the seventh transistor is connected to a second initialization voltage line, and
the output current passing region is disposed between the channel of the seventh transistor and the channel of the sixth transistor.

5. The light emitting display device of claim 4, wherein:
the first semiconductor layer further includes a channel of a fifth transistor,
one end of the fifth transistor is connected to the driving voltage line, and
the channel of the sixth transistor and the channel of the fifth transistor overlap the light emitting control line in a plan view.

6. The light emitting display device of claim 4, wherein:
the first semiconductor layer further includes a channel of a second transistor, and
one end of the second transistor is connected to a data line.

7. The light emitting display device of claim 6, further comprising:
a third data conductive layer disposed between the second organic layer and the anode and disposed on the second organic layer; and
a third organic layer covering the third data conductive layer, and
the anode is disposed directly on the third organic layer.

8. The light emitting display device of claim 7, wherein:
the data line is disposed in the third data conductive layer.

9. The light emitting display device of claim 8, wherein:
the third data conductive layer further includes a third anode connecting electrode, and
the third anode connecting electrode connects the second anode connecting electrode and the anode.

10. The light emitting display device of claim 1, further comprising:
a metal layer disposed between the substrate and the first semiconductor layer and including an extension; and
a buffer layer disposed between the metal layer and the first semiconductor layer,
wherein the extension portion of the metal layer overlaps the channel of the driving transistor in a plan view.

11. A light emitting display device, comprising:
a first semiconductor layer disposed on a substrate and including a channel of a driving transistor;
a first gate conductive layer disposed on the first semiconductor layer and including a gate electrode of the driving transistor overlapping the channel of the driving transistor;
a second gate conductive layer disposed on the first gate conductive layer and including a first storage electrode overlapping the gate electrode of the driving transistor in a plan view and a lower shielding layer;
a second semiconductor layer disposed on the second gate conductive layer and including a channel of a fourth transistor overlapping the lower shielding layer in a plan view;
a third gate conductive layer disposed on the second semiconductor layer and including an initialization control line overlapping the channel of the fourth transistor;
a first data conductive layer disposed on the third gate conductive layer and including a first connection electrode and a first anode connecting electrode connecting the gate electrode of the driving transistor and one side of the channel of the fourth transistor;
a first organic layer covering the first data conductive layer;
a second data conductive layer disposed on the first organic layer and including a second anode connecting electrode electrically connected to the first anode connecting electrode and a driving voltage line;
second organic layers disposed on the second data conductive layer; and
an anode disposed on the second organic layer and electrically connected to the second anode connecting electrode,
wherein the lower shielding layer has an island-like structure, and
wherein the initialization control line is electrically connected to the lower shielding layer through an opening.

12. The light emitting display device of claim 11, wherein:
the second gate conductive layer further includes a lower second scan line,
the second semiconductor layer further includes a channel of a third transistor,
the third gate conductive layer further includes an upper second scan line,
the channel of the third transistor overlaps the lower second scan line and the upper second scan line in a plan view, and
the same signal is applied to the lower second scan line and the upper second scan line.

13. The light emitting display device of claim 12, wherein:
the first semiconductor layer further includes a channel of a sixth transistor and an output current passing region disposed on one side of the channel of the sixth transistor,
the second gate conductive layer further includes a shielding layer overlapping the output current passing region in a plan view,
the initialization control line overlaps the output current passing region and the shielding layer disposed on one side of the channel of the sixth transistor in a plan view, and
the shielding layer is connected to the driving voltage line.

14. The light emitting display device of claim 13, wherein:
the first semiconductor layer further includes a channel of a seventh transistor,
one end of the seventh transistor is connected to a second initialization voltage line, and
the output current passing region is disposed between the channel of the seventh transistor and the channel of the sixth transistor.

15. The light emitting display device of claim 14, wherein:
the first semiconductor layer further including a channel of a fifth transistor,
one end of the fifth transistor being connected to the driving voltage line, and
the channel of the sixth transistor and the channel of the fifth transistor overlapping the light emitting control line in a plan view.

16. The light emitting display device of claim 12, wherein:
the first semiconductor layer further includes a channel of a second transistor, and
one end of the second transistor is connected to a data line.

17. The light emitting display device of claim 16, further comprising:
a third data conductive layer disposed between the second organic layer and the anode and disposed on the second organic layer; and
a third organic layer covering the third data conductive layer,
wherein the anode is disposed directly on the third organic layer.

18. The light emitting display device of claim 17, wherein:
the data line is disposed in the third data conductive layer.

19. The light emitting display device of claim 12, wherein:
the third data conductive layer further includes a third anode connecting electrode, and
the third anode connecting electrode connects the second anode connecting electrode and the anode.

20. The light emitting display device of claim 12, further comprising:
a metal layer disposed between the substrate and the first semiconductor layer and including an extension; and
a buffer layer disposed between the metal layer and the first semiconductor layer, and
wherein the extension portion of the metal layer overlaps the channel of the driving transistor in a plan view.
